(19) United States
(12) Patent Application Publication
(10) Pub. No.: US 2025/0246238 A1
(43) Pub. Date: Jul. 31, 2025

(54) NAND ARRAY INDUCTORS

(71) Applicant: Micron Technology, Inc., Boise, ID (US)

(72) Inventors: Srivatsan Venkatesan, Gopanpalle (IN); Kaveri Jain, Hyderabad (IN); Rajat Vishnoi, Bangalore (IN); Sushma Dogiparthi, Hyderabad (IN); Salil Shashikant Mujumdar, Nanakaramguda (IN)

(21) Appl. No.: 19/036,948

(22) Filed: Jan. 24, 2025

Related U.S. Application Data
(60) Provisional application No. 63/625,556, filed on Jan. 26, 2024.

(51) Int. Cl. G11C 16/04; G11C 5/06; G11C 5/08

(52) U.S. Cl. CPC G11C 16/0483; G11C 5/063; G11C 5/08

(57) ABSTRACT

An inductor is formed on-chip with a memory sub-component comprising at least one three-dimensional (3D) NAND memory component. The inductor is solenoid-like in shape with at least one turn formed of vias and connections. The inductor includes at least a first set of vias, each via in the first set of vias being conductive and having a central axis that is parallel to central axes of the other vias of the first set of vias, the first set of vias including at least a first via, a second via, and a third via. The on-chip inductor further includes a first lower connection electrically connecting the first via and the second via. The on-chip inductor further includes a first upper connection electrically connecting the second via and the third via.

### PRIORITY APPLICATION

This application claims the benefit of priority to U.S. Provisional Application Ser. No. 63/625,556, filed Jan. 26, 2024, which is incorporated herein by reference in its entirety.

### BACKGROUND

Inductors play an important role in power circuits, but are largely absent from on-chip integration. Power circuits, such as DC boost converters, DC buck converters, t-coils, among others, frequently make use of inductors to store energy and solve complex engineering problems. Additionally, conventional inductors are relatively expensive to manufacture due to material constraints.

In NAND arrays, charge pumps are conventionally used to generate high voltage. These charge pumps are highly inefficient. For example, a charge pump that boosts a 2.5V supply to ˜31V typically has a lower efficiency. These charge pumps are also area inefficient, taking up a large amount of on-chip area.

### BRIEF DESCRIPTION OF THE SEVERAL VIEWS OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

To easily identify the discussion of any particular element or act, the most significant digit or digits in a reference number refer to the figure number in which that element is first introduced.

FIG. 1 illustrates an environment including a memory device, according to some examples.

FIG. 2 illustrates schematic diagrams of an example of a 3D NAND architecture semiconductor memory array, according to some examples.

FIG. 3 illustrates schematic diagrams of an example of a 3D NAND architecture semiconductor memory array, according to some examples.

FIG. 4 illustrates a block diagram of a memory module, according to some examples.

FIG. 5 illustrates an aspect of the subject matter in accordance with one embodiment.

FIG. 6 illustrates a representation of an embodiment of an example 3D NAND memory device, according to some examples.

FIG. 7A illustrates an example inductor in an isometric view, according to some examples.

FIG. 7B illustrates an example inductor in a top-down view, according to some examples.

FIG. 8A illustrates an example inductor in an isometric view, according to some examples.

FIG. 8B illustrates an example inductor in a top-down view, according to some examples.

FIG. 8C illustrates an example inductor during formation in a top-down view, according to some examples

FIG. 8D illustrates an example inductor during formation in a cross-sectional view, according to some examples.

FIG. 9A illustrates an example inductor in an isometric view, according to some examples.

FIG. 9B illustrates an example inductor in a top-down view, according to some examples.

FIG. 10A illustrates an example arrangement of a plurality of contacts in a top-down view, according to some examples.

FIG. 10B illustrates an example arrangement of a plurality of contacts in a top-down view, according to some examples.

FIG. 10C illustrates an example arrangement of a plurality of contacts in a top-down view, according to some examples.

FIG. 11A illustrates an example NAND plane with an on-chip inductor, according to some examples.

FIG. 11B illustrates an example NAND die, according to some examples.

FIG. 12 is a flow diagram of features of an example method of forming an inductor, according to various embodiments.

FIG. 13 is a flow diagram of features of an example method of forming an inductor, according to various embodiments.

### DETAILED DESCRIPTION

Challenges to implementing a semiconductor-based or integrated circuit-based, on-chip inductor can include achieving a useful inductance density and q-factor. For example, desirable characteristics of an on-chip inductor include an inductance density on the order of 100's of nH per square millimeter, and a large q-factor. In an example, a useful on-chip inductor can have a low internal resistance to achieve a high q-factor, for example, less than 100 ohms.

In various examples, an on-chip inductor can be formed using similar structures used to implement NAND memory. NAND flash memory uses via-like conductive contact structures with a relatively large vertical height. A solenoid inductor can be formed using, for example, these NAND structures with one or more modifications. The solenoid inductor using NAND structures has high inductance density and q-factor. According to some examples, a boost converter uses the on-chip solenoid inductor.

The term “solenoid” is used herein and should be recognized by one of ordinary skill in the art to represent electromagnets having helical and helical-like shapes. An example of a solenoid is an electromechanically inductive wire wound around an armature to form a round coil. Should the same wire be wound into a coil with right angles forming a square or rectangular cross-section, the resultant electromagnet is also considered a solenoid.

The following detailed description refers to the accompanying drawings that show, by way of illustration, various examples that can be implemented. These examples are described in sufficient detail to enable those of ordinary skill in the art to practice these and other examples. Other examples can be utilized, and structural, logical, mechanical, and electrical changes can be made to these examples. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various examples are not necessarily mutually exclusive, as some examples can be combined with one or more other examples to form new examples. The following detailed description is, therefore, not to be taken in a limiting sense.

Memory devices are typically provided as internal, semiconductor, integrated circuits in computers or other electronic devices. There are many different types of memory, including volatile and non-volatile memory.

Volatile memory requires power to maintain its data, and includes random-access memory (RAM), dynamic random-access memory (DRAM), or synchronous dynamic random-access memory (SDRAM), among others.

Non-volatile memory can retain stored data when not powered, and includes flash memory, read-only memory (ROM), electrically erasable programmable ROM (EEPROM), static RAM (SRAM), erasable programmable ROM (EPROM), resistance variable memory, such as phase-change random-access memory (PCRAM), resistive random-access memory (RRAM), magnetoresistive random-access memory (MRAM), or 3D XPoint™ memory, among others.

Flash memory is utilized as non-volatile memory for a wide range of electronic applications. Flash memory devices typically include one or more groups of one-transistor, floating gate or charge trap memory cells that allow for high memory densities, high reliability, and low power consumption.

Two common types of flash memory array architectures include NAND and NOR architectures, named after the logic form in which the basic memory cell configuration of each is arranged. The memory cells of the memory array are typically arranged in a matrix. In an example, the gates of each floating gate memory cell in a row of the array are connected to an access line (e.g., a word line). In a NOR architecture, the drains of each memory cell in a column of the array are connected to a data line (e.g., a bit line). In a NAND architecture, the drains of each memory cell in a string of the array are connected together in series, source to drain, between a source line and a bit line.

Both NOR and NAND architecture semiconductor memory arrays are accessed through decoders that activate specific memory cells by selecting the word line connected to their gates. In a NOR architecture semiconductor memory array, once activated, the selected memory cells place their data values on bit lines, causing different currents to flow depending on the state at which a particular cell is programmed. In a NAND architecture semiconductor memory array, a high bias voltage is applied to a drain-side select gate (SGD) line. Word lines connected to the gates of the unselected memory cells of each group are driven at a specified pass voltage (e.g., Vₚₐₛₛ) to operate the unselected memory cells of each group as pass transistors (e.g., to pass current in a manner unrestricted by their stored data values). Current then flows from the source line to the bit line through each series connected group, restricted only by the selected memory cells of each group, placing current encoded data values of selected memory cells on the bit lines.

Each flash memory cell in a NOR or NAND architecture semiconductor memory array can be programmed individually or collectively to one or a number of programmed states. For example, a single-level cell (SLC) can represent one of two programmed states (e.g., 1 or 0), representing one bit of data.

However, flash memory cells can also represent one of more than two programmed states, allowing the manufacture of higher density memories without increasing the number of memory cells, as each cell can represent more than one binary digit (e.g., more than one bit). Such cells can be referred to as multi-state memory cells, multi-digit cells, or multi-level cells (MLCs). In certain examples, MLC can refer to a memory cell that can store two bits of data per cell (e.g., one of four programmed states), a triple-level cell (TLC) can refer to a memory cell that can store three bits of data per cell (e.g., one of eight programmed states), and a quad-level cell (QLC) can store four bits of data per cell. MLC is used herein in its broader context, to can refer to any memory cell that can store more than one bit of data per cell (i.e., that can represent more than two programmed states).

Traditional memory arrays are two-dimensional (2D) structures arranged on a surface of a semiconductor substrate. To increase memory capacity for a given area, and to decrease cost, the size of the individual memory cells has decreased. However, there is a technological limit to the reduction in size of the individual memory cells, and thus, to the memory density of 2D memory arrays. In response, three-dimensional (3D) memory structures, such as 3D NAND architecture semiconductor memory devices, are being developed to further increase memory density and lower memory cost.

Such 3D NAND devices often include strings of storage cells, connected in series (e.g., drain to source), between one or more source-side select gates (SGSs) proximate a source, and one or more drain-side select gates (SGDs) proximate a bit line. In an example, the SGSs or the SGDs can include one or more field-effect transistors (FETs) or metal-oxide semiconductor (MOS) structure devices, etc. In some examples, the strings will extend vertically, through multiple vertically spaced tiers containing respective word lines. A semiconductor structure (e.g., a polysilicon structure) may extend adjacent a string of storage cells to form a channel for the storages cells of the string. In the example of a vertical string, the polysilicon structure may be in the form of a vertically extending via. In some examples the string may be “folded,” and thus arranged relative to a U-shaped via. In other examples, multiple vertical structures may be stacked upon one another to form stacked arrays of storage cell strings.

Memory arrays or devices can be combined together to form a storage volume of a memory system, such as a solid-state drive (SSD), a Universal Flash Storage (UFS™) device, a MultiMediaCard (MMC) solid-state storage device, an embedded MMC device (eMMC™), etc. An SSD can be used as, among other things, the main storage device of a computer, having advantages over traditional hard drives with moving parts with respect to, for example, performance, size, weight, ruggedness, operating temperature range, and power consumption. For example, SSDs can have reduced seek time, latency, or other delay associated with magnetic disk drives (e.g., electromechanical, etc.). SSDs use non-volatile memory cells, such as flash memory cells to obviate internal battery supply requirements, thus allowing the drive to be more versatile and compact.

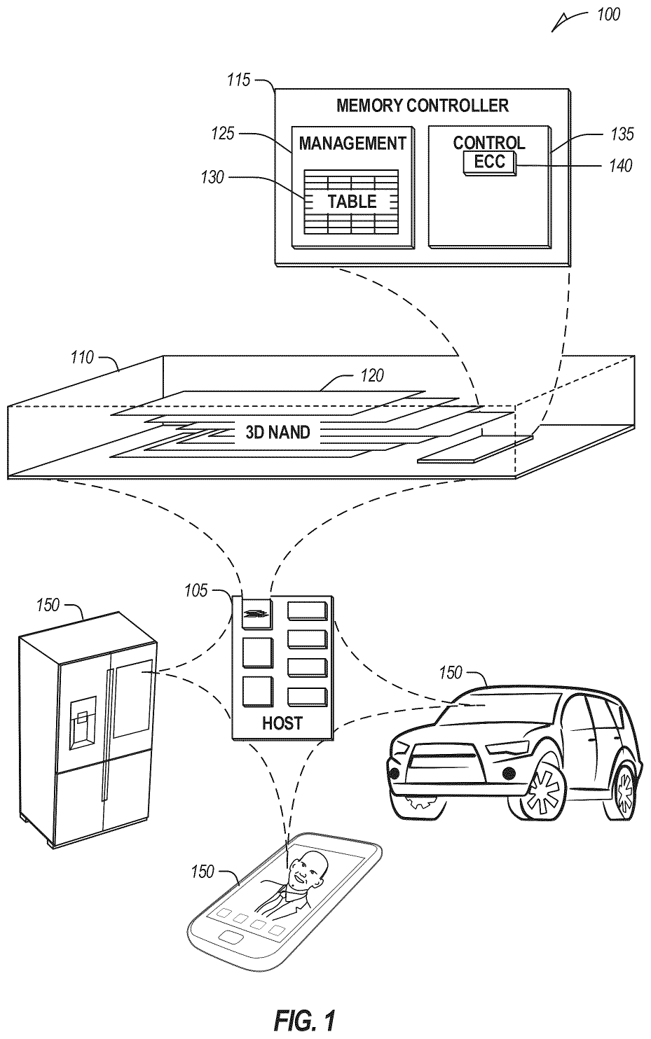

FIG. 1 illustrates an example of an environment 100 including a host device 105 and a memory device 110 configured to communicate over a communication interface. The host device 105 or the memory device 110 may be included in a variety of products 150, such as Internet of Things (IoT) devices (e.g., a refrigerator or other appliance, sensor, motor or actuator, mobile communication device, automobile, drone, etc.) to support processing, communications, or control of the product 150.

The memory device 110 includes a memory controller 115 and a memory array 120 including, for example, a number of individual memory die (e.g., three-dimensional (3D) NAND die). In 3D architecture semiconductor memory technology, vertical structures are stacked, increasing the number of tiers, physical pages, and accordingly, the density of a memory device (e.g., a storage device). In an example, the memory device 110 can be a discrete memory or storage device component of the host device 105. In other examples, the memory device 110 can be a portion of an integrated circuit (e.g., system on a chip (SOC), etc.), stacked or otherwise included with one or more other components of the host device 105.

One or more communication interfaces can be used to transfer data between the memory device 110 and one or more other components of the host device 105, such as a Serial Advanced Technology Attachment (SATA) interface, a Peripheral Component Interconnect Express (PCIe) interface, a Universal Serial Bus (USB) interface, a Universal Flash Storage (UFS) interface, an eMMC™ interface, or one or more other connectors or interfaces. The host device 105 can include a host system, an electronic device, a processor, a memory card reader, or one or more other electronic devices external to the memory device 110. In some examples, the host 105 may be a machine having some portion, or all, of the components discussed in reference to the machine 1700 of 17.

The memory controller 115 can receive instructions from the host 105, and can communicate with the memory array, such as to transfer data to (e.g., write or erase) or from (e.g., read) one or more of the memory cells, planes, sub-blocks, blocks, or pages of the memory array. The memory controller 115 can include, among other things, circuitry or firmware, including one or more components or integrated circuits. For example, the memory controller 115 can include one or more memory control units, circuits, or components configured to control access across the memory array 120 and to provide a translation layer between the host 105 and the memory device 110. The memory controller 115 can include one or more input/output (I/O) circuits, lines, or interfaces to transfer data to or from the memory array 120. The memory controller 115 can include a memory manager 125 and an array controller 135.

The memory manager 125 can include, among other things, circuitry or firmware, such as a number of components or integrated circuits associated with various memory management functions. For purposes of the present description example memory operation and management functions will be described in the context of NAND memory. Persons skilled in the art will recognize that other forms of non-volatile memory may have analogous memory operations or management functions. Such NAND management functions include wear leveling (e.g., garbage collection or reclamation), error detection or correction, block retirement, or one or more other memory management functions. The memory manager 125 can parse or format host commands (e.g., commands received from a host) into device commands (e.g., commands associated with operation of a memory array, etc.), or generate device commands (e.g., to accomplish various memory management functions) for the array controller 135 or one or more other components of the memory device 110.

The memory manager 125 can include a set of management tables 130 configured to maintain various information associated with one or more component of the memory device 110 (e.g., various information associated with a memory array or one or more memory cells connected to the memory controller 115). For example, the management tables 130 can include information regarding block age, block erase count, error history, or one or more error counts (e.g., a write operation error count, a read bit error count, a read operation error count, an erase error count, etc.) for one or more blocks of memory cells connected to the memory controller 115. In certain examples, if the number of detected errors for one or more of the error counts is above a threshold, the bit error can be referred to as an uncorrectable bit error. The management tables 130 can maintain a count of correctable or uncorrectable bit errors, among other things.

The array controller 135 can include, among other things, circuitry or components configured to control memory operations associated with writing data to, reading data from, or erasing one or more memory cells of the memory device 110 connected to the memory controller 115. The memory operations can be based on, for example, host commands received from the host 105, or internally generated by the memory manager 125 (e.g., in association with wear leveling, error detection or correction, etc.).

The array controller 135 can include an error correction code (ECC) component 140, which can include, among other things, an ECC engine or other circuitry configured to detect or correct errors associated with writing data to or reading data from one or more memory cells of the memory device 110 connected to the memory controller 115. The memory controller 115 can be configured to actively detect and recover from error occurrences (e.g., bit errors, operation errors, etc.) associated with various operations or storage of data, while maintaining integrity of the data transferred between the host 105 and the memory device 110, or maintaining integrity of stored data (e.g., using redundant RAID storage, etc.), and can remove (e.g., retire) failing memory resources (e.g., memory cells, memory arrays, pages, blocks, etc.) to prevent future errors.

In some examples, the memory array may comprise a number of NAND dies and one or more functions of the memory controller 115 for a particular NAND die may be implemented on an on-die controller on that particular die. Other organizations and delineations of control functionality may also be utilized, such as a controller for each die, plane, superblock, block, page, and the like.

The memory array 120 can include several memory cells arranged in, for example, a number of devices, semiconductor dies, planes, sub-blocks, blocks, or pages. In operation, data is typically written to or read from the NAND memory device 110 in pages, and erased in blocks. However, one or more memory operations (e.g., read, write, erase, etc.) can be performed on larger or smaller groups of memory cells, as desired. The data transfer size of a NAND memory device 110 is typically referred to as a page, whereas the data transfer size of a host is typically referred to as a sector.

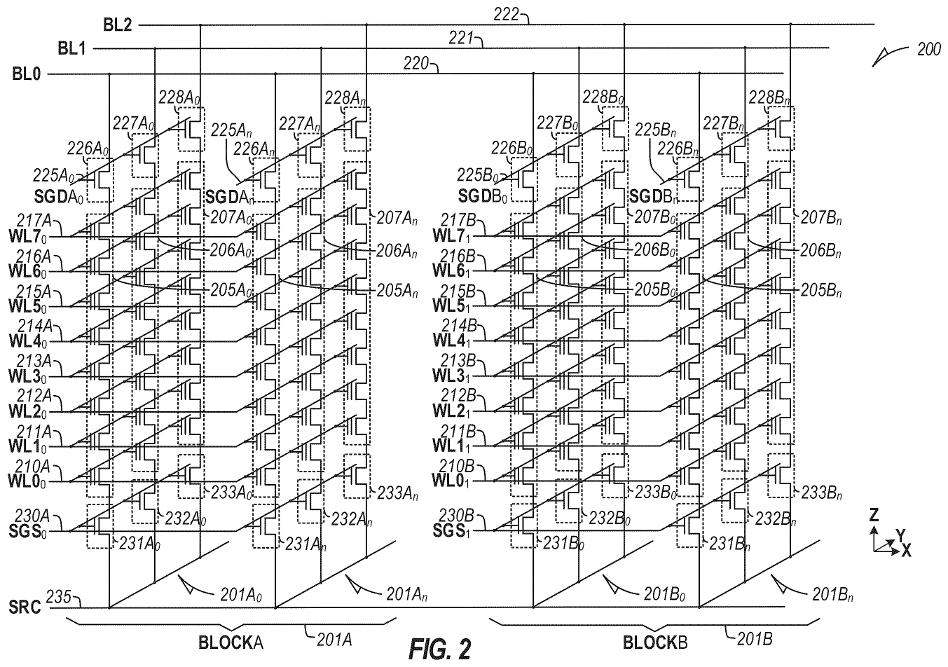

FIG. 2 illustrates an example schematic diagram of a 3D NAND architecture semiconductor memory array 200 including a number of strings of memory cells (e.g., first-third A₀ memory strings 205A₀-207A₀, first-third Aₙ memory strings 205Aₙ-207Aₙ, first-third B₀ memory strings 205B₀-207B₀, first-third Bₙ memory strings 205Bₙ-207Bₙ, etc.), organized in blocks (e.g., block A 201A, block B 201B, etc.) and sub-blocks (e.g., sub-block A₀ 201A₀, sub-block Aₙ 201Aₙ, sub-block B₀ 201B₀, sub-block Bₙ 201Bₙ, etc.). The memory array 200 represents a portion of a greater number of similar structures that would typically be found in a block, device, or other unit of a memory device.

Each string of memory cells includes a number of tiers of charge storage transistors (e.g., floating gate transistors, charge-trapping structures, etc.) stacked in the Z direction, source to drain, between a source line (SRC) 235 or a source-side select gate (SGS) (e.g., first-third A₀ SGS 231A₀-233A₀, first-third Aₙ SGS 231Aₙ-233Aₙ, first-third B₀ SGS 231B₀-233B₀, first-third Bₙ SGS 231Bₙ-233Bₙ, etc.) and a drain-side select gate (SGD) (e.g., first-third A₀ SGD 226A₀-228A₀, first-third Aₙ SGD 226Aₙ-228Aₙ, first-third B₀ SGD 226B₀-228B₀, first-third Bₙ SGD 226Bₙ-228Bₙ, etc.). Each string of memory cells in the 3D memory array can be arranged along the X direction as data lines (e.g., bit lines (BL) BL0-BL2 220-222), and along the Y direction as physical pages.

Within a physical page, each tier represents a row of memory cells, and each string of memory cells represents a column. A sub-block can include one or more physical pages. A block can include a number of sub-blocks (or physical pages) (e.g., 128, 256, 384, etc.). Although illustrated herein as having two blocks, each block having two sub-blocks, each sub-block having a single physical page, each physical page having three strings of memory cells, and each string having 8 tiers of memory cells, in other examples, the memory array 200 can include more or fewer blocks, sub-blocks, physical pages, strings of memory cells, memory cells, or tiers. For example, each string of memory cells can include more or fewer tiers (e.g., 16, 32, 64, 128, etc.), as well as one or more additional tiers of semiconductor material above or below the charge storage transistors (e.g., select gates, data lines, etc.), as desired. As an example, a 48 GB TLC NAND memory device can include 18,592 bytes (B) of data per page (16,384+2208 bytes), 1536 pages per block, 548 blocks per plane, and 4 or more planes per device.

Each memory cell in the memory array 200 includes a control gate (CG) connected to (e.g., electrically or otherwise operatively connected to) an access line (e.g., word lines (WL) WL0₀-WL7₀ 210A-217A, WL0₁-WL7₁ 210B-217B, etc.), which collectively connects the control gates (CGs) across a specific tier, or a portion of a tier, as desired. Specific tiers in the 3D memory array, and accordingly, specific memory cells in a string, can be accessed or controlled using respective access lines. Groups of select gates can be accessed using various select lines. For example, first-third A₀ SGD 226A₀-228A₀ can be accessed using an A₀ SGD line SGDA₀ 225A₀, first-third Aₙ SGD 226Aₙ-228Aₙ can be accessed using an Aₙ SGD line SGDAₙ 225Aₙ, first-third B₀ SGD 226B₀-228B₀ can be accessed using an B₀ SGD line SGDB₀ 225B₀, and first-third Bₙ SGD 226Bₙ-228Bₙ can be accessed using an Bₙ SGD line SGDBₙ 225Bₙ. First-third A₀ SGS 231A₀-233A₀ and first-third Aₙ SGS 231Aₙ-233Aₙ can be accessed using a gate select line SGS₀ 230A, and first-third B₀ SGS 231B₀-233B₀ and first-third Bₙ SGS 231Bₙ-233Bₙ can be accessed using a gate select line SGS₁ 230B.

In an example, the memory array 200 can include a number of tiers of semiconductor material (e.g., polysilicon, etc.) configured to connect the control gates (CGs) of each memory cell or select gate (or a portion of the CGs or select gates) of a respective tier of the array. Specific strings of memory cells in the array can be accessed, selected, or controlled using a combination of bit lines (BLs) and select gates, etc., and specific memory cells at one or more tiers in the specific strings can be accessed, selected, or controlled using one or more access lines (e.g., word lines).

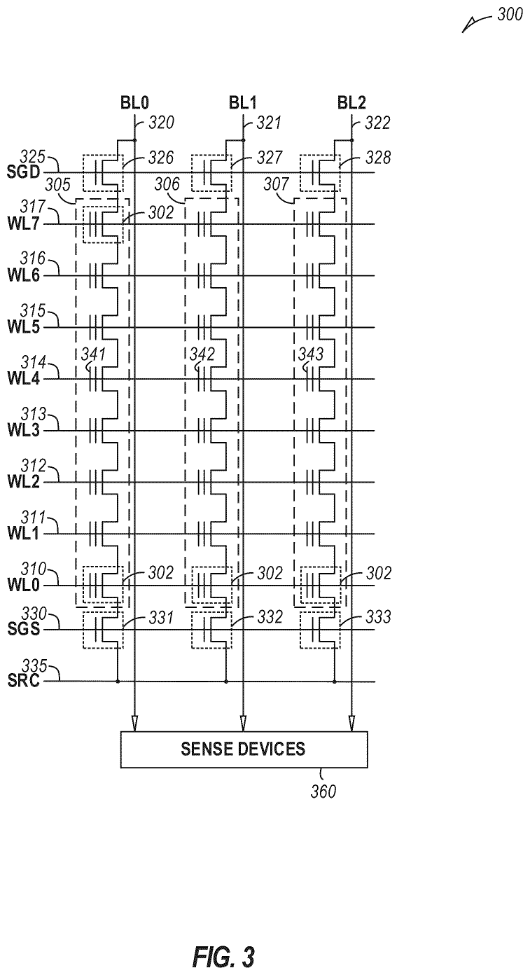

FIG. 3 illustrates an example schematic diagram of a portion of a NAND architecture semiconductor memory array 300 including a plurality of memory cells 302 arranged in a two-dimensional array of strings (e.g., first-third strings 305-307) and tiers (e.g., illustrated as respective word lines (WL) WL0-WL7 310-317, a drain-side select gate (SGD) line 325, a source-side select gate (SGS) line 330, etc.), and sense amplifiers or devices 360. For example, the memory array 300 can illustrate an example schematic diagram of a portion of one physical page of memory cells of a 3D NAND architecture semiconductor memory device, such as illustrated in FIG. 2.

Each string of memory cells is connected to a source line (SRC) using a respective source-side select gate (SGS) (e.g., first-third SGS 331-333), and to a respective data line (e.g., first-third bit lines (BL) BL0-BL2 320-322) using a respective drain-side select gate (SGD) (e.g., first-third SGD 326-328). Although illustrated with 8 tiers (e.g., using word lines (WL) WL0-WL7 310-317) and three data lines (BL0-BL2 326-328) in the example of FIG. 3, other examples can include strings of memory cells having more or fewer tiers or data lines, as desired.

In a NAND architecture semiconductor memory array, such as the example memory array 300, the state of a selected memory cell 302 can be accessed by sensing a current or voltage variation associated with a particular data line containing the selected memory cell. The memory array 300 can be accessed (e.g., by a control circuit, one or more processors, digital logic, etc.) using one or more drivers. In an example, one or more drivers can activate a specific memory cell, or set of memory cells, by driving a particular potential to one or more data lines (e.g., bit lines BL0-BL2), access lines (e.g., word lines WL0-WL7), or select gates, depending on the type of operation desired to be performed on the specific memory cell or set of memory cells.

To program or write data to a memory cell, a programming voltage (Vpgm) (e.g., one or more programming pulses, etc.) can be applied to selected word lines (e.g., WL4), and thus, to a control gate of each memory cell connected to the selected word lines (e.g., first-third control gates (CGs) 341-343 of the memory cells connected to WL4). Programming pulses can begin, for example, at or near 15V, and, in certain examples, can increase in magnitude during each programming pulse application. While the program voltage is applied to the selected word lines, a potential, such as a ground potential (e.g., Vss), can be applied to the data lines (e.g., bit lines) and substrates (and thus the channels, between the sources and drains) of the memory cells targeted for programming, resulting in a charge transfer (e.g., direct injection or Fowler-Nordheim (FN) tunneling, etc.) from the channels to the floating gates of the targeted memory cells.

In contrast, a pass voltage (Vpass) can be applied to one or more word lines having memory cells that are not targeted for programming, or an inhibit voltage (e.g., Vcc) can be applied to data lines (e.g., bit lines) having memory cells that are not targeted for programming, for example, to inhibit charge from being transferred from the channels to the floating gates of such non-targeted memory cells. The pass voltage can be variable, depending, for example, on the proximity of the applied pass voltages to a word line targeted for programming. The inhibit voltage can include a supply voltage (Vcc), such as a voltage from an external source or supply (e.g., a battery, an AC-to-DC converter, etc.), relative to a ground potential (e.g., Vss).

As an example, if a programming voltage (e.g., 15V or more) is applied to a specific word line, such as WL4, a pass voltage of 10V can be applied to one or more other word lines, such as WL3, WL5, etc., to inhibit programming of non-targeted memory cells, or to retain the values stored on such memory cells not targeted for programming. As the distance between an applied program voltage and the non-targeted memory cells increases, the pass voltage required to refrain from programming the non-targeted memory cells can decrease. For example, where a programming voltage of 15V is applied to WL4, a pass voltage of 10V can be applied to WL3 and WL5, a pass voltage of 8V can be applied to WL2 and WL6, a pass voltage of 7V can be applied to WL1 and WL7, etc. In other examples, the pass voltages, or number of word lines, etc., can be higher or lower, or more or less.

The sense amplifiers 360, connected to one or more of the data lines (e.g., first, second, or third bit lines (BL0-BL2) 320-322), can detect the state of each memory cell in respective data lines by sensing a voltage or current on a particular data line.

Between applications of one or more programming pulses (e.g., Vpgm), a verify operation can be performed to determine if a selected memory cell has reached its intended programmed state. If the selected memory cell has reached its intended programmed state, it can be inhibited from further programming. If the selected memory cell has not reached its intended programmed state, additional programming pulses can be applied. If the selected memory cell has not reached its intended programmed state after a particular number of programming pulses (e.g., a maximum number), the selected memory cell, or a string, block, or page associated with such selected memory cell, can be marked as defective.

To erase a memory cell or a group of memory cells (e.g., erasure is typically performed in blocks or sub-blocks), an erasure voltage (Vers) (e.g., typically Vpgm) can be applied to the substrates (and thus the channels, between the sources and drains) of the memory cells targeted for erasure (e.g., using one or more bit lines, select gates, etc.), while the word lines of the targeted memory cells are kept at a potential, such as a ground potential (e.g., Vss), resulting in a charge transfer (e.g., direct injection or Fowler-Nordheim (FN) tunneling, etc.) from the floating gates of the targeted memory cells to the channels.

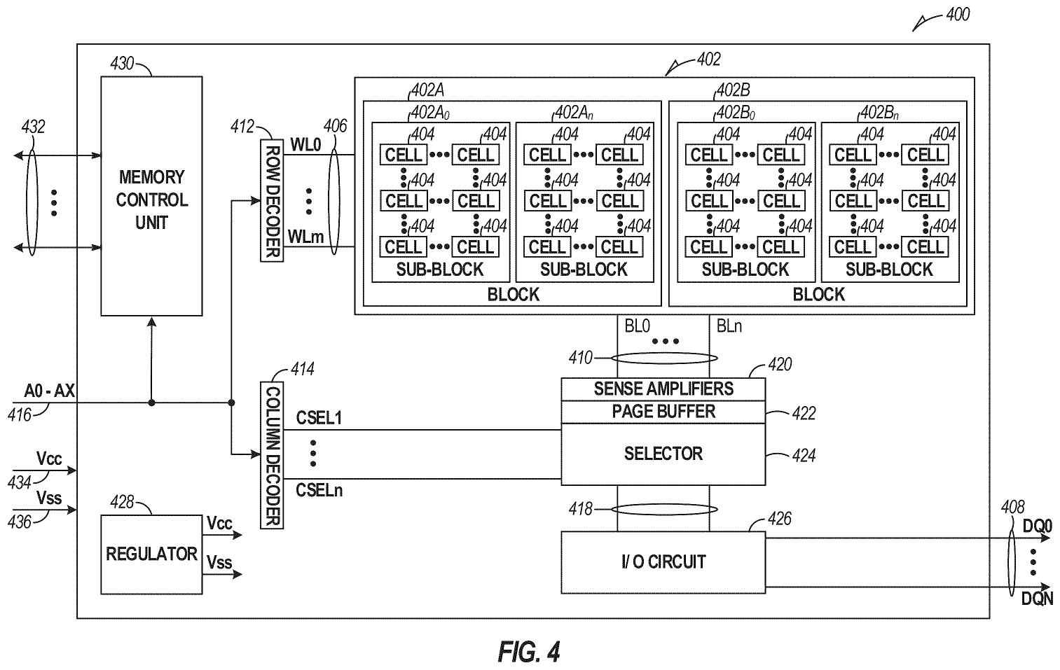

FIG. 4 illustrates an example block diagram of a memory device 400 including a memory array 402 having a plurality of memory cells 404, and one or more circuits or components to provide communication with, or perform one or more memory operations on, the memory array 402. The memory device 400 can include a row decoder 412, a column decoder 414, sense amplifiers 420, a page buffer 422, a selector 424, an input/output (I/O) circuit 426, and a memory control unit 430.

The memory cells 404 of the memory array 402 can be arranged in blocks, such as first and second blocks 402A, 402B. Each block can include sub-blocks. For example, the first block 402A can include first and second sub-blocks 402A₀, 402Aₙ, and the second block 402B can include first and second sub-blocks 402B₀, 402Bₙ. Each sub-block can include a number of physical pages, each page including a number of memory cells 404. Although illustrated herein as having two blocks, each block having two sub-blocks, and each sub-block having a number of memory cells 404, in other examples, the memory array 402 can include more or fewer blocks, sub-blocks, memory cells, etc. In other examples, the memory cells 404 can be arranged in a number of rows, columns, pages, sub-blocks, blocks, etc., and accessed using, for example, access lines 406, first data lines 410, or one or more select gates, source lines, etc.

The memory control unit 430 can control memory operations of the memory device 400 according to one or more signals or instructions received on control lines 432, including, for example, one or more clock signals or control signals that indicate a desired operation (e.g., write, read, erase, etc.), or address signals (A0-AX) received on one or more address lines 416. One or more devices external to the memory device 400 can control the values of the control signals on the control lines 432, or the address signals on the address line 416. Examples of devices external to the memory device 400 can include, but are not limited to, a host, a memory controller, a processor, or one or more circuits or components not illustrated in FIG. 4.

The memory device 400 can use access lines 406 and first data lines 410 to transfer data to (e.g., write or erase) or from (e.g., read) one or more of the memory cells 404. The row decoder 412 and the column decoder 414 can receive and decode the address signals (A0-AX) from the address line 416, can determine which of the memory cells 404 are to be accessed, and can provide signals to one or more of the access lines 406 (e.g., one or more of a plurality of word lines (WL0-WLm)) or the first data lines 410 (e.g., one or more of a plurality of bit lines (BL0-BLn)), such as described above.

The memory device 400 can include sense circuitry, such as the sense amplifiers 420, configured to determine the values of data on (e.g., read), or to determine the values of data to be written to, the memory cells 404 using the first data lines 410. For example, in a selected string of memory cells 404, one or more of the sense amplifiers 420 can read a logic level in the selected memory cell 404 in response to a read current flowing in the memory array 402 through the selected string to the data lines 410.

One or more devices external to the memory device 400 can communicate with the memory device 400 using the I/O lines (DQ0-DQN) 408, address lines 416 (A0-AX), or control lines 432. The input/output (I/O) circuit 426 can transfer values of data in or out of the memory device 400, such as in or out of the page buffer 422 or the memory array 402, using the I/O lines 408, according to, for example, the control lines 432 and address lines 416. The page buffer 422 can store data received from the one or more devices external to the memory device 400 before the data is programmed into relevant portions of the memory array 402, or can store data read from the memory array 402 before the data is transmitted to the one or more devices external to the memory device 400.

The column decoder 414 can receive and decode address signals (A0-AX) into one or more column select signals (CSEL1-CSELn). The selector 424 (e.g., a select circuit) can receive the column select signals (CSEL1-CSELn) and select data in the page buffer 422 representing values of data to be read from or to be programmed into memory cells 404. Selected data can be transferred between the page buffer 422 and the I/O circuit 426 using second data lines 418.

The memory control unit 430 can receive positive and negative supply signals, such as a supply voltage (Vcc) 434 and a negative supply (Vss) 436 (e.g., a ground potential), from an external source or supply (e.g., an internal or external battery, an AC-to-DC converter, etc.). In certain examples, the memory control unit 430 can include a regulator 428 to internally provide positive or negative supply signals.

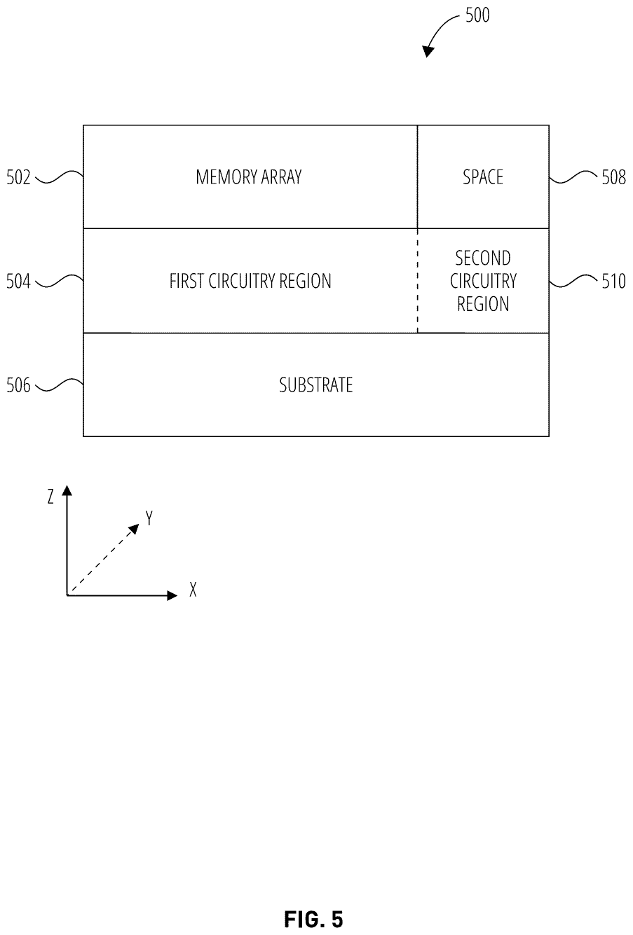

FIG. 5 is a block diagram of regions of an embodiment of an example memory device 500 having a 3D memory array, in which the regions are shown in the z-x plane. Memory arrays are being designed as 3D structures in memory devices to increase memory density. The 3D memory array extends in a horizontal plane along a substrate, which can be designated as a x-y plane, and in a vertical direction, taken as the z direction perpendicular to the x-y plane. Other design considerations can be implemented with the 3D memory arrays such as using a circuit under array architecture to enhance reduction of die size or increase utilization of space in a die.

A memory array region 502 having horizontal planes (x-y planes) of memory cells is disposed vertically over a first circuitry region 504 disposed in a substrate 506. The horizontal planes (x-y planes) of memory cells can be structured as multiple arranged tiers comprising memory cells. The first circuitry region 504 includes control circuitry for the memory array of the memory array region 502. The first circuitry region 504 can include control logic and sensing circuitry for sensing the programmed data states of memory cells of the memory array. With the control logic and sensing circuitry fabricated below the memory array using semiconductor processing that can include CMOS (Complementary Metal Oxide Semiconductor). The control circuitry in the first circuitry region 504 can be implemented with one or more circuits structured in a n-well ring for resistive ground domain segregation.

The control circuitry can include one or more instrumentalities similar to row decoder 412, column decoder 414, sense amplifiers 420, page buffer 422, selector 424, I/O circuit 426, and memory control unit 430 of memory device 400 shown in FIG. 4. A space 508 is adjacent the memory array region 502 and above the first circuitry region 504. The space 508 can be implemented beyond the horizontal extent of the memory array and may not directly contain elements of the control and sensing circuitry for the memory array, which can be located in the first circuitry region 504.

The first circuitry region 504 can include circuitry located directly below the 3D memory array of memory array region 502 such that this region extends at least in one direction in the x-y plane to the same extent as the 3D memory array extends in this direction. The first circuitry region 504 can include a region in the die outside of the horizontal extent of the 3D memory array, referred to as outside array (OA), and below a level of the 3D memory array. In various embodiments, circuits or contacts can be structured outside the horizontal extent of and below a level of the 3D memory array. The circuits in this OA region can be referred to as circuits outside array in a second circuitry region 510. The space of the second circuitry region 510 can be disposed adjacent the portion of the space of the first circuitry region 504 that contains control circuitry for the memory array of the memory array region 502 and below the level of the 3D memory array.

With the memory device 500 having a second circuitry region 510 adjacent the first circuitry region 504 containing control circuitry for the memory array, and placed below a level of the memory array in memory array region 502, the space 508 can be arranged directly over the second circuitry region 510. The second circuitry region 510 can include pads to connect to nodes for external connections or pins of the package for the memory device 500. The space 508 can also be implemented with conductive columns to connect to the top levels of the memory device 500.

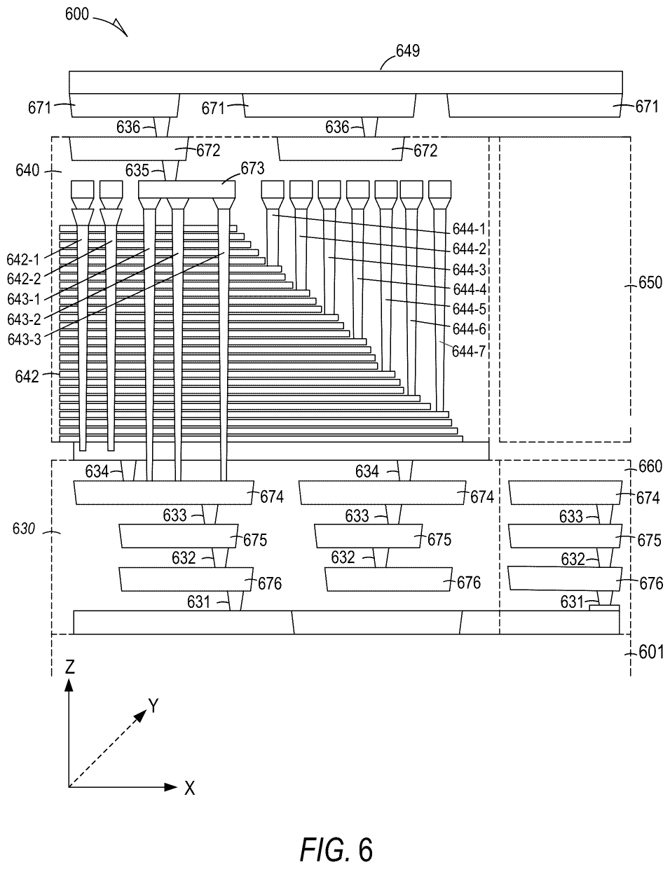

FIG. 6 is a representation of an embodiment of an example 3D NAND memory device 600 having a 3D memory array, in which the regions are shown in a vertical cross-section in the z-x plane. A memory array region 640 having horizontal planes (x-y planes) of memory cells is disposed vertically over a first circuitry region 630 disposed in a substrate 601. The horizontal planes (x-y planes) of memory cells are structured as multiple arranged tiers 642 comprising memory cells. The first circuitry region 630 includes control circuitry for the memory array of the memory array region 640.

The control circuitry in the first circuitry region 630 can be implemented with one or more circuits structured in a n-well ring for resistive ground domain segregation. The control circuitry can include one or more instrumentalities similar to row decoder 412, column decoder 414, sense amplifiers 420, page buffer 422, selector 424, I/O circuit 426, and memory control unit 430 of memory device 400 of FIG. 4 or other circuits to control access to selected memory cells of the tiers 542.

A space 650, similar to the space 508 of FIG. 5, is adjacent the memory array region 640 and above the first circuitry region 630. The 3D NAND memory device 600 can have a second circuitry region 660, as part of the first circuitry region 630, adjacent the section of the first circuitry region 630 containing the control circuitry and sensing circuitry of the memory array in memory array region 640, and below a level of the memory array in memory array region 640. The space 650 can be arranged directly over the second circuitry region 660. The second circuitry region 660 can include pads to connect to nodes for external connections or pins of the package for the memory device 600. The space 650 can use conductive columns to connect to the top levels of the memory device 600.

FIG. 6 illustrates some of the elements of a NAND memory device having a 3D memory array. For discussion purposes, a small number of structural elements are shown in FIG. 6. Memory cells of the tiers 642 can extend from vias such as vias 642-1 and 642-2. Though only two such vias are shown, other such vias are located with respect to the tiers 642. The 3D NAND memory device 600 can include, but is not limited in number to, conductive contact vias 643-1, 643-2, and 643-3 along with conductive plugs 644-1 . . . 644-7. The vias 642-1 and 642-2, the conductive contact vias 643-1, 643-2, and 643-3, and the conductive plugs 644-1 . . . 644-7 can extend above and below tiers 642 and can contact different metallization levels, which can be at various vertical locations in the structure of the 3D memory array of the memory array region 640, such that access to the memory cells in the tiers 642 can be attained by a device external to the 3D memory array. The vias 642-1 and 642-2, the conductive contact vias 643-1, 643-2, and 643-3, and the conductive plugs 644-1 . . . 644-7, and other similar structures provide vertical connections extending though the 3D memory array or through memory breaks within the 3D memory array, which vertical connections can be used to connect to sensing circuitry and other control logic of the first circuitry region 630 for the 3D memory array.

As a non-limiting example, FIG. 6 shows metal layers 674, metal layers 675, and metal layers 676 in the first circuitry region 630, where these metal layers provide electrical connection with circuit elements in the first circuitry region 630. In some embodiments, metal layers may be replaced with conductively doped semiconductor material, such as but not limited to conductively doped polysilicon. Electrical connections between metal layers or conductive semiconductor layers at different vertical levels in the first circuitry region 630 can be provided by conductive contact vias labelled 631, 632, 633, 634. Similarly, the second circuitry region 660 can include metal layer 647, metal layers 675, and metal layers 676 to provide electrical connection with circuit elements in the second circuitry region 660.

At the top of the memory region 640 are metal layers 672, which metal layers can interface with a number of metallization layers 671. The metallization layers 671 can be top metallizations for the die containing the 3D NAND memory device 600 and can be covered by a passivation layer 649. The passivation layer 649 is an electrically insulating layer and can include one or more materials such as, but not limited to, tetraethyl orthosilicate (TEOS) and an oxynitride. The oxynitride, for example, can include silicon oxynitride. The various metal layers 672 layers can connect to various metallization layers 671 by different contact vias 636 and can connect to the conductive contact vias 643-1, 643-2, and 643-3 in the memory array region 640.

The conductive contact vias 643-1, 643-2, and 643-3, which are conductive vias in the memory array region 640, can be long conductive vias, relative to the conductive contact vias 631, 632, 633, 634, 635, and 636. The conductive contact vias 643-1, 643-2, and 643-3 can connect to metal layers 674 in the first circuitry region 630. Other such relatively long structures such as the conductive contact vias 643-1, 643-2, and 643-3 can also terminate in a different metal layer 673.

In a memory chip, such as but not limited to a 3D NAND memory die with a circuitry under array architecture, pumps circuits can be localized in specific regions of the chip. These pump circuits can inject a relatively high current onto ground. Current injection on ground for a power delivery network from pump circuits can cause peak-to-peak noise signals on the order of tens or hundreds of millivolts and can affect sensing in page buffer circuits, which can be sensitive to tens of mV. This can especially affect an intermediate word line architecture. In such an architecture, when a plane is performing a sensing operation, another plane can be in a pump phase, which can be noisy, and cross-talk between the planes can lead to improper readings.

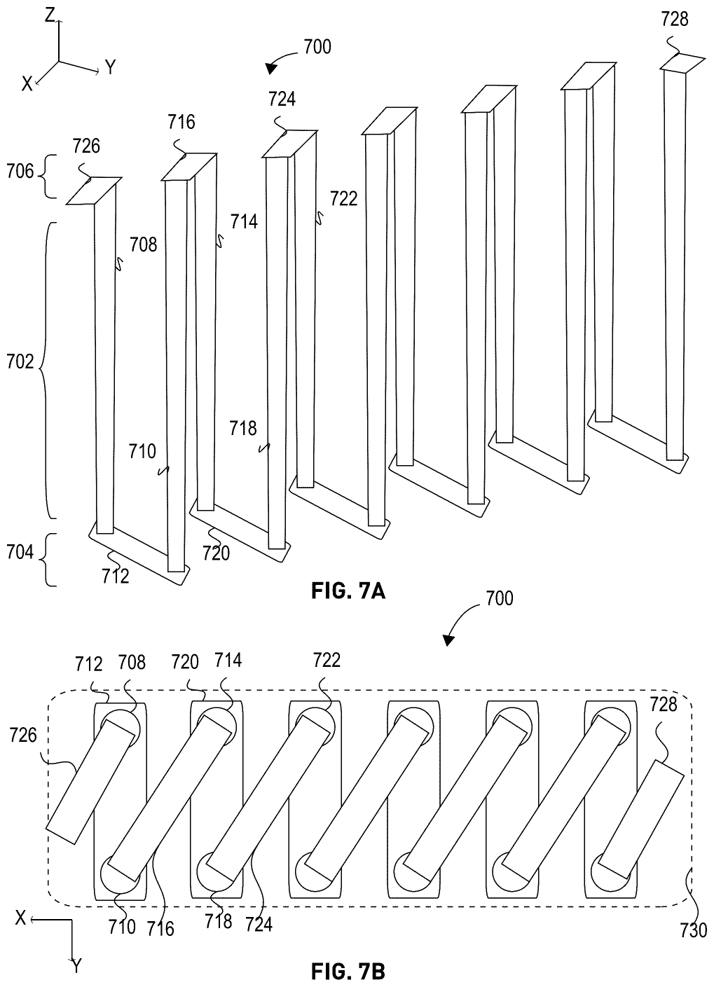

FIG. 7A illustrates an example inductor 700 in an isometric view, according to some examples. The inductor 700 is formed using one or more structures formed during or in coordination with 3D NAND structure fabrication, such as a set of vias 702, according to some examples. The inductor 700 is formed by making one or more modifications to the one or more existing 3D NAND structures, such as a set of lower connections 704 and a set of upper connections 706 to form a solenoid shape.

According to some examples, the inductor 700 is formed on-chip adjacent to at least one 3D NAND memory device. For example, the inductor 700 is formed in a space adjoining the 3D NAND memory array, such as the space 650 of FIG. 6. According to some examples, the inductor 700 is used to store charge for the 3D NAND memory array. For example, a boost converter may use the inductor 700 for charge storage.

The set of vias 702 are a set of long conductive vias that extend vertically (z-direction), according to some examples. That is, the vias in the set of vias 702 are oriented parallel to one another. In other words, each via in the set of vias has a central axis that is parallel to central axes of the other vias of the set of vias. According to some examples, the long conductive vias extend a length that exceeds a thickness of multiple layers of the NAND substrate stack. The set of vias 702 are formed of a conductive material, according to some examples. A via in the set of vias 702 can have a variety of cross-sectional shapes, such as circular, oval, square, rectangular, hexagonal, among others. According to some examples, each via in the set of vias 702 has the same cross-sectional shape.

The set of vias 702 can be formed during fabrication of a 3D NAND memory device, according to some examples. According to some examples, the set of vias 702 comprise an embodiment of the conductive contact vias 643-1, 643-2, and 643-3 in the example of FIG. 6. According to some examples, the set of vias 702 are formed on a space adjacent to the 3D NAND memory array, such as the space 650 adjacent to the memory array region 640 of FIG. 6. In some examples, the set of vias 702 extend from the second circuitry region 660 toward the passivation layer 649. For example, in embodiments where the memory array region 640 is ˜15 microns tall, the set of vias 702 are approximately less than or equal to ˜15 microns tall. The set of vias 702 may be formed by the same process as formation of the conductive contact vias 643-1, 643-2, 643-3 of the 3D NAND device. In some examples, the set of vias 702 and the conductive contact vias 643-1, 643-2, 643-3 are formed in the same step.

The set of lower connections 704 are a set of conductive connections. A lower connection in the set of lower connections 704 connects one via in the set of vias 702 to another via, according to some examples. In particular, the lower connection connects the lower end of the one via (e.g., negative z-direction) to the lower end of an adjacent via, according to some examples. As such, the set of lower connections 704 are the conductive connections located nearer to the second circuitry region 660 (e.g., the second circuitry region 660) and/or the substrate (e.g, the substrate 601), according to some examples.

The set of lower connections 704 are oriented perpendicular (or approximately perpendicular) to the set of vias 702, according to some examples. For example, the set of vias 702 are oriented in the z-direction and the set of lower connections 704 are in the x-y plane, oriented substantially parallel to the y-axis in FIG. 7A. Each lower connection in the set of lower connections 704 are oriented parallel to one another, according to some examples.

The set of lower connections 704 are formed during some processes of fabricating a 3D NAND memory device, according to some examples. According to some examples, the set of lower connections 704 are an embodiment of the metal layers 674 in FIG. 6. In particular, in examples where the second circuitry region 660 includes the metal layer 674, metal layers 675, and metal layers 676 can provide electrical connection with circuit elements in the second circuitry region 660. Additionally, or alternatively, the set of lower connections 704 are formed of a conductive material, such as tungsten.

The set of lower connections 704 can be formed by any fabrication processes used to form the metallic layers 674, or any other metal layer in a 3D NAND memory device. For example, a hard mask can be applied and selectively etched to form holes in the desired shapes of the lower connections 704. A metal (or other conductive material) can be deposited to fill the holes in the mask. The mask can then be etched away, leaving the set of lower connections 704. According to some examples, the set of lower connections 704 are formed after formation of the lower structures of the second circuitry region 660, such as 631, 676, 632, 675, and 633. According to some examples, the set of lower connections 704 are formed prior to forming the set of vias 702.

According to some examples, forming the set of lower connections 704 comprises the one or more modification made to existing 3D NAND structures to form the inductor 700. For example, conventional second circuitry region 660 can include metallic layer 674. However, the set of lower connections 704 comprises one or more lower connections, according to some examples. Accordingly, formation of a plurality of lower connections in the set of lower connections 704 may constitute one or more modifications to the conventional 3D NAND structure that includes a singular metal layer 674.

The set of upper connections 706 are a set of conductive members that connect one or more vias. An upper connection in the set of upper connections 706 connects one via in the set of vias 702 to another via, according to some examples. In particular, the upper connection connects the upper end of one via (e.g., positive z-direction) to the upper end of another via, according to some examples. As such, the set of upper connections 706 are the conductive connections located nearer to the passivation layer 649, according to some examples.

The set of upper connections 706 comprise conductive members that extend perpendicular (or approximately perpendicular) to the set of vias 702, according to some examples. For example, the set of vias 702 are oriented in the z-direction and the set of upper connections 706 are in the x-y plane, oriented substantially parallel to the x-axis in FIG. 7A. Each upper connection in the set of upper connections 706 is oriented parallel to the other upper connections, according to some examples.

The set of upper connections 706 can be formed as one or more modifications to existing 3D NAND structures, according to some examples. The set of upper connections 706 can be formed using processes similar to those for forming other connections and/or contacts for 3D NAND structures. The set of upper connections 706 are formed of a conductive material, such as a metal.

The set of upper connections 706 can be formed after formation of the set of vias 702, according to some examples. In some examples, the set of upper connections 706 can be formed through a metallization process, such as a damascene process, a trench deposition process, or other metal deposition methods.

The set of vias 702, the set of lower connections 704, and the set of upper connections 706 are continuously electrically connected to form the solenoid-shaped inductor 700. For example, a first via 708 is connected to a second via 710 by a first lower connection 712. In particular, the first via 708 is electrically connected to the first lower connection 712 at one end of the first lower connection 712. The opposite end of the first lower connection 712 is electrically connected to the second via 710.

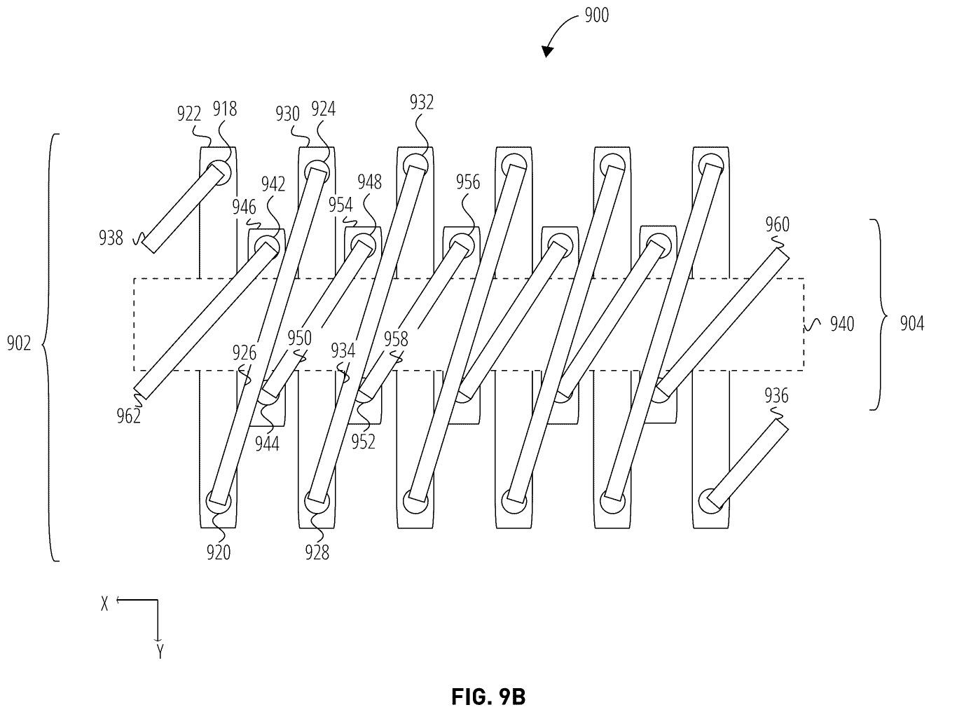

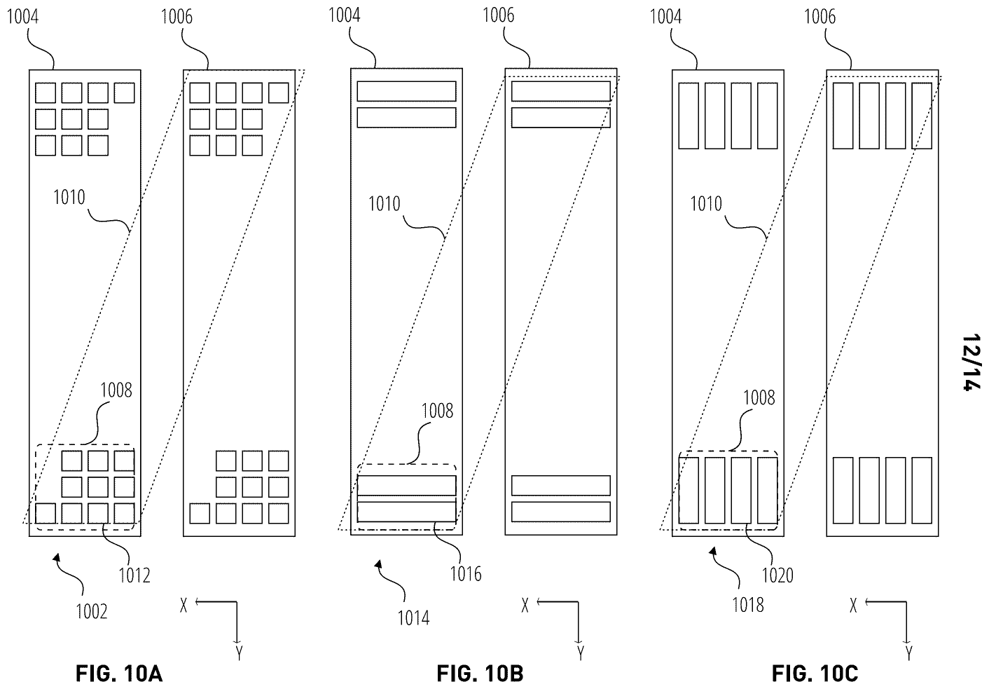

According to some examples, the first via 708 and the second via 710 are electrically connected to an upper surface of the first lower connection 712 (e.g., x-y plane facing positive z-direction). In particular, a bottom surface of the first via 708 (e.g., x-y plane facing negative z-direction) is electrically connected to the upper surface of the first lower connection 712, according to some examples. Other vias in the set of vias 702 may be connected to other lower connections in the set of lower connections 704 in the same manner. Examples of electrical connections between the first via 708 and the first lower connection 712 are described in further detail with respect to FIG. 10A, FIG. 10B, and FIG. 10C.

The second via 710 is connected to a third via 714 by a first upper connection 716, according to some examples. For example, the second via 710 is electrically connected to the first upper connection 716 at one end of the first upper connection 716. The opposite end of the first upper connection 716 is electrically connected to the third via 714.

The third via 714 is connected to a fourth via 718 by a second lower connection 720 in a manner already described with respect to the first via 708, second via 710, and first lower connection 712, according to some examples. The fourth via 718 is connected to a fifth via 722 by a second upper connection 724 in a manner already described with respect to the second via 710, the third via 714, and the first upper connection 716, according to some examples, and so on.

The first via 708, the first lower connection 712, the second via 710, and the first upper connection 716 form a first turn of the solenoid-shaped inductor 700, according to some examples. The third via 714, the second lower connection 720, the fourth via 718, and the second upper connection 724 form a second turn of the solenoid shaped inductor 700. The pattern continues for N turns, where the inductor 700 has N turns and N is any positive number. For example, the inductor may have on the order of 10's of turns. According to some embodiments, each inductor 700 has 2N vias in the set of vias 702, N lower connections in the set of lower connections 704, and N upper connections in the set of upper connections 706.

In the example of FIG. 7A, the first via 708, the second via 710, the third via 714, the fourth via 718, and the fifth via 722 are included in the set of vias 702. According to some examples, the set of vias 702 has 2N vias. The first lower connection 712 and the second lower connection 720 are included in the set of lower connections 704. According to some examples, the set of lower connections 704 has N lower connections. The first upper connection 716 and the second upper connection 724 are included in the set of upper connections 706. According to some examples, the set of upper connections 706 has N upper connections. The number of vias and connections depicted in FIG. 7A are provided for illustrative clarity and are not meant to be limiting.

The example of the inductor 700 includes a start contact 726 and an end contact 728 to electrically connect the inductor 700 to a bias signal source or other power source. Thus, when a bias signal is applied, current travels from the start contact 726 to the first via 708 to the first lower connection 712 to the second via 710 to the first upper connection 716, and so on, until the current exits the inductor 700 via the end contact 728. The start contact 726 and the end contact 728 may take any length, shape, and/or cross-section to fit design constraints. As depicted in FIG. 7A, the start contact 726 and the end contact 728 can be grouped with the set of upper connections 706. In other examples, the start contact 726 and/or end contact 728 may be grouped with the set of lower connections 704, depending on design constraints. Additionally, the start contact 726 and the end contact 728 may be formed alongside the set of lower connections 704 and/or the set of upper connections 706, depending on their respective positioning within the inductor 700. In an example, the inductor 700 can include intermediate contacts or taps in the conductive path between the start contact 726 and the end contact 728.

The fabrication processes of the inductor 700 are highly scalable. For example, each via in the set of vias 702 can be formed simultaneously, each lower connection in the set of lower connections 704 can be formed simultaneously, and each upper connection in the set of upper connections 706 can be formed simultaneously. That is, the time consumed by inductor 700 fabrication can be substantially independent of the number of turns in the solenoid shape. Accordingly, the number of turns in the solenoid-shaped inductor 700 can be increased to increase inductance without impacting fabrication timelines.

FIG. 7B illustrates an example inductor 700 in a top-down view, according to some examples. The top-down view is of the x-y plane, flattening the depiction of the inductor 700 along the z-axis. The set of lower connections 704 extend in the y-direction. The set of vias 702 have been flattened in the z-direction and are depicted with circular cross-sections in the example of FIG. 7B. The set of upper connections 706 extend on a diagonal in the x-direction, each upper connection providing contact between two vias. For example, the second via 710 is connected to the third via 714 by the first upper connection 716.

According to some examples, the second via 710 and the third via 714 are electrically connected to a lower surface of the first upper connection 716 (e.g., x-y plane facing negative z-direction). In particular, an upper surface of the second via 710 (e.g., x-y plane facing positive z-direction) is electrically connected to the lower surface of the first upper connection 716, according to some examples. Other vias in the set of vias 702 may be connected to other upper connections in the set of upper connections 706 in the same manner. Examples of electrical connections are described in further detail with respect to FIG. 10A, FIG. 10B, and FIG. 10C.

The top-down view more clearly depicts that the set of vias 702 is comprised of two rows of vias. For example, the first via 708, the third via 714, the fifth via 722, and so on, form a first row of vias. The second via 710, the fourth via 718, and so on form a second row of vias. The first row of vias and the second row of vias are parallel to one another in the illustrated example. Other orientations or via alignment can be similarly used.

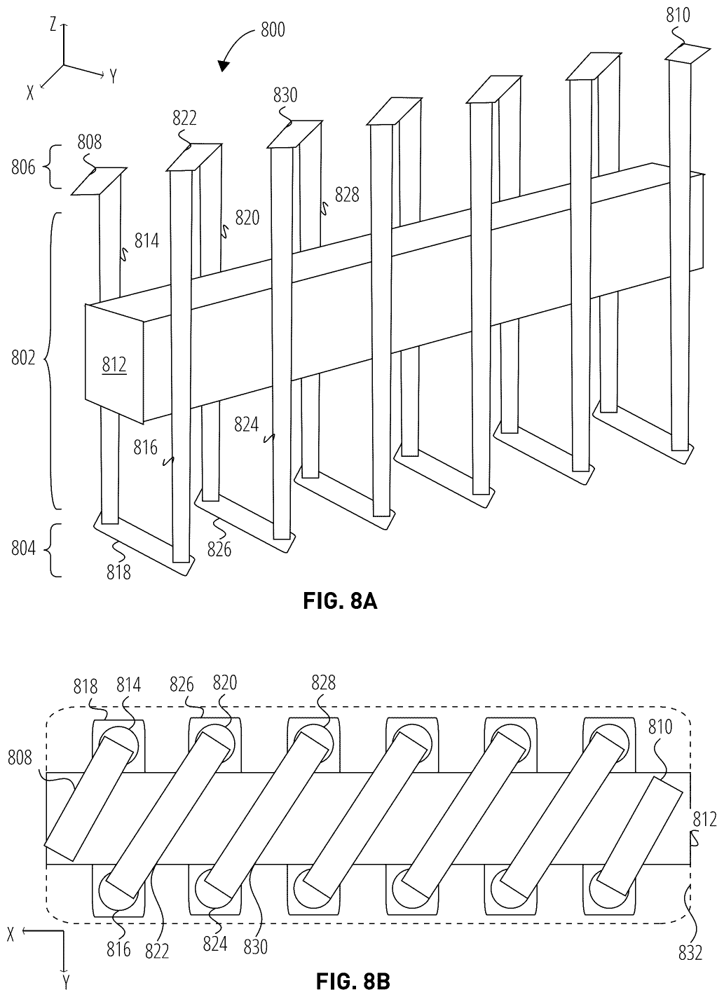

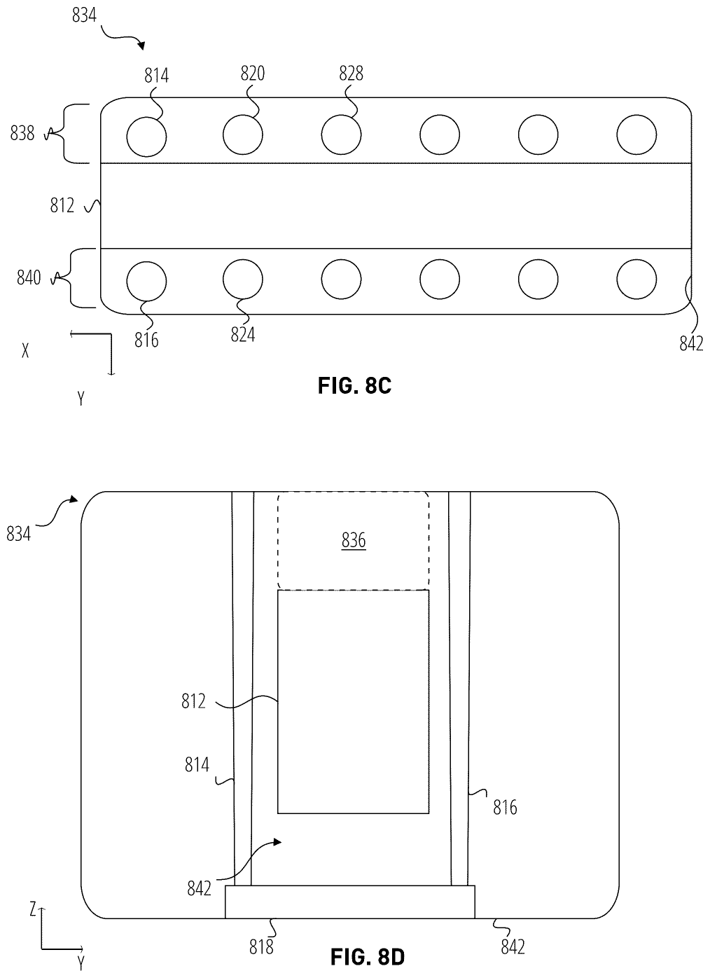

FIG. 8A illustrates an example inductor 800 in an isometric view, according to some examples. The inductor 800 is formed using one or more structures formed during or in coordination with 3D NAND structure fabrication, such as a set of vias 802, according to some examples. The inductor 800 is formed by making one or more modifications to the one or more existing 3D NAND structures, such as a set of lower connections 804 and a set of upper connections 806 to form a solenoid shape.

The inductor 800 is an example of the inductor 700, according to some examples. The set of vias 802, which can comprise an example of the set of vias 702, is a set of discrete conductive vias. The set of lower connections 804, which can comprise an example of the set of lower connections 704, and the set of upper connections 806, which can comprise an example of the set of upper connections 706, are each a set of conductive members that are used to form various electrical connections. The start contact 808 and the end contact 810, which can comprise an example of the start contact 726 and the end contact 728, provide electrical connection to ends of the inductor 800.

According to some examples, the inductor 800 has a magnetic core 812 to increase inductance of the inductor 800. The magnetic core 812 is a block of ferromagnetic material within the confines of the set of vias 802, the set of lower connections 804, and the set of upper connections 806. The magnetic core 812 can be formed of any ferromagnetic material or, according to some embodiments, a metal. For example, the magnetic core 812 is formed of a cobalt titanium zirconium alloy (CoTaZr), such as Co₉₀Ta₅Zr₅ alloy, which has a permeability of ˜600 Henries/meter; a significant increase as compared to the permeability of free space of 4×10⁻⁷ Henries/meter.

For example, a first via 814 is connected to a second via 816 by a first lower connection 818. The second via 816 is connected to a third via 820 by a first upper connection 822. The first via 814 electrically connected to the first lower connection 818, the first lower connection 818 electrically connected to the second via 816, and the second via 816 electrically connected to the first upper connection 822 form a first turn of the solenoid-shaped inductor 800. A first portion of the magnetic core 812 is contained within, or extends through, the first turn.

Further continuing with the example, the third via 820 is connected to a fourth via 824 by a second lower connection 826. The fourth via 824 is connected to a fifth via 828 by a second upper connection 830. The third via 820 electrically connected to the second lower connection 826, the second lower connection 826 electrically connected to the fourth via 824, and the fourth via 824 electrically connected to the second upper connection 830 form a second turn of the solenoid-shaped inductor 800. A second portion of the magnetic core 812 is contained within, or extends through, the second turn.

According to some examples, the inductor 800 has N turns, as previously discussed in relation to FIG. 7A. According to some examples, the magnetic core 812 extends through or within the N turns. According to some examples, the magnetic core 812 may extend further in length (x-direction) than the turns of the inductor 800. According to some examples, the magnetic core 812 has a length (x-direction) shorter than the inductor 800. The illustration of the magnetic core 812 having a rectangular cross-section in FIG. 8A is not meant to be limiting; other cross-sectional shapes are possible, such as round. In an example, multiple different and separate magnetic core structures can be provided and extend within respective portions of the inductor 800. Taps or contacts can be provided such that multiple discrete inductors can be provided adjacent to one another.

FIG. 8B illustrates an example of the inductor 800 in a top-down view, according to some examples. The top-down view shows the conductors of the inductor 800 extending around portions of the magnetic core 812 from another view. For example, the first via 814 is connected to the second via 816 by the first lower connection 818, where the first lower connection 818 is underneath the magnetic core 812. The set of lower connections 804 is below the magnetic core 812. The second via 816 is connected to the third via 820 by the first upper connection 822, where the first upper connection 822 is above the magnetic core 812. The set of upper connections 806 is above the magnetic core 812. That is, the magnetic core 812 is encircled or enclosed within the bounds of the set of lower connections 804 and the set of upper connections 806, according to some examples.

According to some examples, the inductor 800 is filled with an oxide 832. The oxide 832 insulates the inductor 800, according to some examples. The oxide 832 seals the magnetic core 812 on at least one side, according to some examples. For example, as depicted in FIG. 8B, the magnetic core 812 is surrounded by the oxide 832 on all sides of the magnetic core 812, According to some examples, the oxide 832 is an inactive layer providing spacing between the magnetic core 812 and the surrounding inductor 800.

FIG. 8C illustrates a top-down view of an example of a partially-formed inductor 834 such as during formation or fabrication, according to some examples. The partially-formed inductor 834 is depicted in FIG. 8C during the formation of the magnetic core 812. A first row of vias 838 includes the first via 814, the third via 820, and the fifth via 828, among other vias. A second row of vias 840 includes the second via 816, the fourth via 824, among other vias. According to some examples, the set of vias 802 is bifurcated into the first row of vias 838 and the second row of vias 840, where the first row of vias 838 is oriented parallel to the second row of vias 840.

According to some examples, the magnetic core 812 is formed after formation of the set of lower connections 804 and the set of vias 802. The partially-formed inductor 834 is filled with a block of oxide 842, which is not necessarily the oxide 832 of the formed inductor 800. The oxide 842 is etched to form an oblong hole running between the first row of vias 838 and the second row of vias 840, where the oblong hole is of the desired length (x-direction) and width (y-direction) of the magnetic core 812. Sputtering may be used to achieve a precise shape of the oblong hole. According to some examples, the oblong hole is of a height (z-direction) greater than that of the resultant magnetic core 812 (see space 836 of FIG. 8D). The oblong hole is at least partially filled with a ferromagnetic material to form the magnetic core 812. According to some examples, the ferromagnetic material is deposited via CVD or PVD.

According to some examples, formation of the magnetic core 812 is more disruptive than excluding the magnetic core 812 (e.g., air core, oxide core) due to other 3D NAND fabrication processes occurring on-chip. For example, dummy tiers of tungsten of the decks are replaced by the ferromagnetic material. According to some examples, the formation of the magnetic core 812 occurs after the formation of metal contacts and prior to slit formation in some 3D NAND fabrication processes.

FIG. 8D illustrates an example of the partially-formed inductor 834 in a cross-sectional view, according to some examples. The cross-sectional view flattens the partially-formed inductor 834 along the x-axis, providing a cross-sectional view of the y-z plane. The cross-sectional view depicts the first via 814 and the second via 816 connected to the first lower connection 818, which are surrounded by and filled with the oxide 842.

The oxide 842 has been etched and filled with the magnetic core 812 in the example illustrated in FIG. 8D. Due to the oblong hole etched being of greater height (z-direction) than the magnetic core 812, a space 836 remains after partially filling the oblong hole. According to some examples, the space 836 is filled with an oxide (e.g., oxide 832, oxide 842). According to some examples, the set of upper connections 806 are formed after filling the space 836.

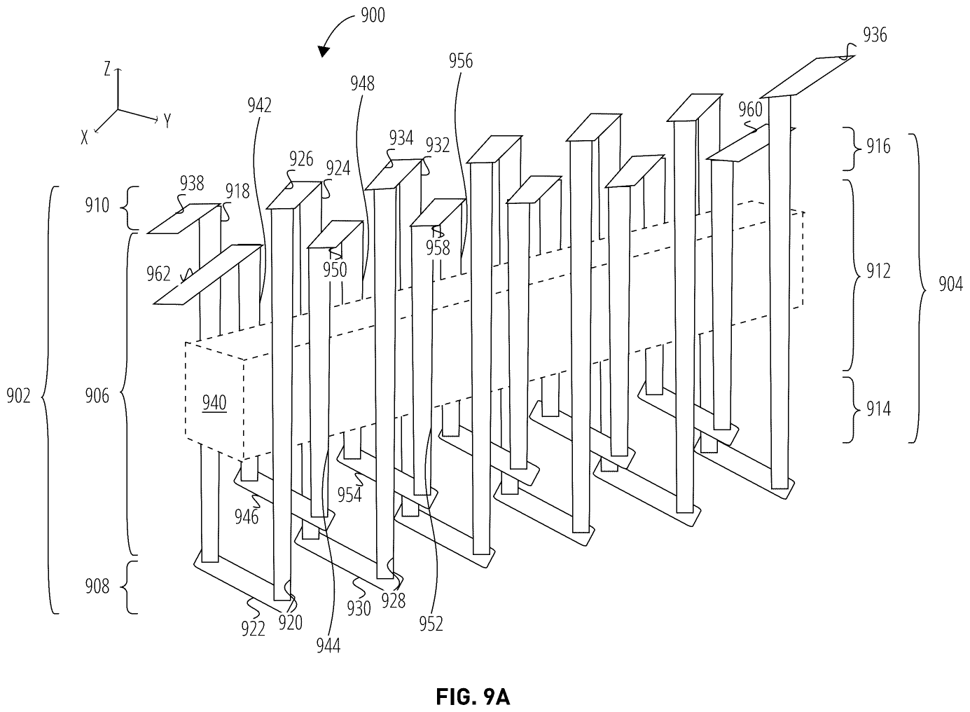

FIG. 9A illustrates an example inductor 900 in an isometric view, according to some examples. The inductor 900 is formed using one or more structures formed during or in coordination with 3D NAND structure fabrication with one or more modifications to the one or more existing 3D NAND structures. The inductor 900 includes an outer solenoid 902 and an inner solenoid 904, according to some examples. The inductor 900 may be referred to as a nested inductor.

The outer solenoid 902 includes an outer set of vias 906, an outer set of lower connections 908, and an outer set of upper connections 910, according to some examples. The outer set of vias 906, which can comprise an example of the set of vias 702, are a set of long conductive vias. The outer set of lower connections 908, which can comprise an example of the set of lower connections 704, and the outer set of upper connections 910, which can comprise an example of the set of upper connections 706, are each a set of conductive connections.

The inner solenoid 904 includes an inner set of vias 912, an inner set of lower connections 914, and an inner set of upper connections 916, according to some examples. The inner set of vias 912, which can comprise an example of the set of vias 702, are a set of long conductive vias. The inner set of lower connections 914, which can comprise an example of the set of lower connections 704, and the inner set of upper connections 916, which can comprise an example of the set of upper connections 706, are each a set of conductive connections.

According to some examples, the inner solenoid 904 is substantially or entirely contained within the “turns” of the outer solenoid 902. For example, a first outer via 918 connects to a second outer via 920 via a first outer lower connection 922. The second outer via 920 connects to a third outer via 924 via a first outer upper connection 926. The third outer via 924 connects to a fourth outer via 928 via a second outer lower connection 930. The fourth outer via 928 connects to a fifth outer via 932 via a second outer upper connection 934. The connection of the first outer via 918 through the fifth outer via 932 forms the first two turns of the outer solenoid 902.

According to some examples, a first inner via 942 is connected to a second inner via 944 via a first inner lower connection 946. The second inner via 944 connects to a third inner via 948 via a first inner upper connection 950. The third inner via 948 connects to a fourth inner via 952 via a second inner lower connection 954. The fourth inner via 952 connects to a fifth inner via 956 via a second inner upper connection 958. The connection of the first inner via 942 through the fifth inner via 956 forms the first two turns of the inner solenoid 904.

The first two turns on the inner solenoid 904 are nested within the turns of the outer solenoid 902. According to some examples, the inner solenoid 904 is wholly contained within the outer set of vias 906, the outer set of lower connections 908, and the outer set of upper connections 910. In some examples, the inner set of vias 912 are of a lesser height (z-direction) than the outer set of vias 906 such that the inner solenoid 904 fits within the outer solenoid 902. According to some examples, the inner set of lower connections 914 are of a length (in the y-direction) less than or equal to that of the outer set of lower connections 908. According to some examples, the inner set of upper connections 916 are of a length (in the x-direction) less than or equal to that of the outer set of upper connections 910.

The outer solenoid 902 and the inner solenoid 904 can be formed by an additive layering process similar to the formation processes of the inductor 700, according to some examples. An example method of forming the inductor 900 is discussed in relation to FIG. 13.

The inclusion of an inner solenoid 904 in the inductor 900 increases the inductance of the inductor 900. A nested inner solenoid 904 has the benefit of increasing inductance without taking up additional on-chip area. The inner solenoid 904 amplifies the magnetic field produced by the outer solenoid 902, and vice versa.

The inductor 900 optionally includes a magnetic core 940. The magnetic core 940, which can comprise an example of the magnetic core 812, is a core of ferromagnetic material. Inclusion of the magnetic core 940 further increases the inductance of the inductor 900 by amplifying the magnetic field generated. In examples containing an outer solenoid 902 and an inner solenoid 904, at least a portion of the magnetic core 940 is provided within the confines of the turns of the inner solenoid 904, as further illustrated in FIG. 9B.

According to some examples, the outer solenoid 902 has an outer start contact 938 and an outer end contact 936, which can comprise an example of the start contact 726 and the end contact 728, respectively, that can electrically connect the outer solenoid 902 to a bias signal or other power source. Likewise, the inner solenoid 904 has an inner start contact 962 and an inner end contact 960, which can comprise an example of the start contact 726 and the end contact 728, respectively, that can electrically connect the inner solenoid 904 to a bias signal or other power source. The outer start contact 938 and inner start contact 962 may be electrically connected together, and the outer end contact 936 and inner end contact 960 may be electrically connected together. Through the respective start and end contacts, the inner solenoid 904 and the outer solenoid 902 may be connected in parallel or in series.

FIG. 9B illustrates an example of the inductor 900 in a top-down view, according to some examples. The top-down view shows the inductor 900 with the outer solenoid 902, the inner solenoid 904, and optional magnetic core 940.

According to some examples, the first outer via 918 is connected to the second outer via 920 by the first outer lower connection 922, where the first outer lower connection 922 is underneath the inner solenoid 904 and the magnetic core 940. In general, the outer set of lower connections 908 is below (z-direction) the inner solenoid 904 and the magnetic core 940, according to some examples. Further, the second outer via 920 is connected to the third outer via 924 by the first outer upper connection 926, where the first outer upper connection 926 is above (z-direction) the inner solenoid 904 and the magnetic core 940. In general, the outer set of lower connections 908 is above the inner solenoid 904 and the magnetic core 812, according to some examples. That is, both the inner solenoid 904 and the magnetic core 940 are within the bounds of the outer solenoid 902, according to some examples.

According to some examples, the first inner via 942 is connected to the second inner via 944 by the first inner lower connection 946, where the first inner lower connection 946 is underneath the magnetic core 940 and above the outer set of lower connections 908. In general, the inner set of lower connections 914 is layered in between the outer set of lower connections 908 above and the magnetic core 940 below, according to some examples. Further, the second inner via 944 is connected to the third inner via 948 by the first inner upper connection 950, where the first inner upper connection 950 is above the magnetic core 940 and below the outer set of upper connections 910. In general, the inner set of upper connections 916 is layered between the magnetic core 940 below and the outer set of upper connections 910 above, according to some examples.

According to some examples, the inner solenoid 904 has fewer turns than the outer solenoid 902. For example, the inner solenoid 904 has N−1 turns if the outer solenoid 902 has N turns. According to some examples, the inner solenoid 904 has the same number of turns as the outer solenoid 902. The illustrations in FIG. 9A and FIG. 9B of the number of turns in the outer solenoid 902 and the inner solenoid 904 are not meant to be limiting.

FIG. 10A illustrates an example arrangement of a plurality of contacts 1002 in a top-down view, according to some examples. A first lower connection 1004 and a second lower connection 1006 are illustrated, each having a plurality of contacts 1002 at each of two ends. A first via 1008 is depicted as a dashed outline and a first upper connection 1010 is depicted as a dotted outline to provide view of the plurality of contacts 1002 underneath. The plurality of contacts 1002 electrically connect a first via 1008 to the first lower connection 1004, according to some examples.

Multiple contacts, such as the plurality of contacts 1002, are used in some examples to minimize the contact resistance of the electrical connection between vias and connections. Multiple contacts can be used to electrically connect any particular via to any particular connection described in this disclosure (e.g., an upper connection or a lower connection).

For commercial use, and in particular use in a boost converter, a sufficiently high inductance density and q-factor are key requirements for an on-chip inductor. For example, for a boost converter for 3D NAND, a useful inductor can have an inductance density on the order of 100's of nH per square millimeter and a large q-factor. Q-factor is driven by internal resistance of the inductor, so keeping internal resistance below 100 Ohms (at 50 MHz) is an additional design requirement. Accordingly, different configurations of contacts can be used to lower the resistance of the on-chip inductor.

In the example of FIG. 10A, the plurality of contacts 1002 are arranged in a grid-like formation, extending in multiple rows and multiple columns of contacts. Each contact in the plurality of contacts 1002 is a square cross-section contact 1012 of roughly uniform size, according to some examples. Other cross-sectional shapes may be used (e.g., round). The precise number and organization of the plurality of contacts 1002 can vary based on design constraints. The plurality of contacts 1002 are organized to maximize electrical contact with the via.

FIG. 10B illustrates an example arrangement of a plurality of contacts 1014 in a top-down view, according to some examples. The plurality of contacts 1014 are arranged in a slotted formation, extending in a single row that can be expanded further down the first lower connection 1004. Each contact in the plurality of contacts 1014 is a transverse rectangle cross-section contact 1016 of roughly uniform size, according to some examples. Each transverse rectangle cross-section contact 1016 spans the width (x-direction) of the first lower connection 1004 and/or the first via 1008, according to some examples. The plurality of contacts 1014 may contain additional or fewer transverse rectangle cross-section contacts 1016, according to some examples.

FIG. 10C illustrates an example arrangement of a plurality of contacts 1018 in a top-down view, according to some examples. The plurality of contacts 1018 are arranged in a parallel formation, spanning in a single row across the width (x-direction) of the first lower connection 1004 and/or the first via 1008, according to some examples. Each contact in the plurality of contacts 1018 is a longitudinal rectangle cross-section contact 1020 of roughly uniform size, according to some examples. Each longitudinal rectangle cross-section contact 1020 extends parallel to the first lower connection 1004. The plurality of contacts 1018 may contain additional or fewer longitudinal rectangle cross-section contacts 1020, according to some examples.

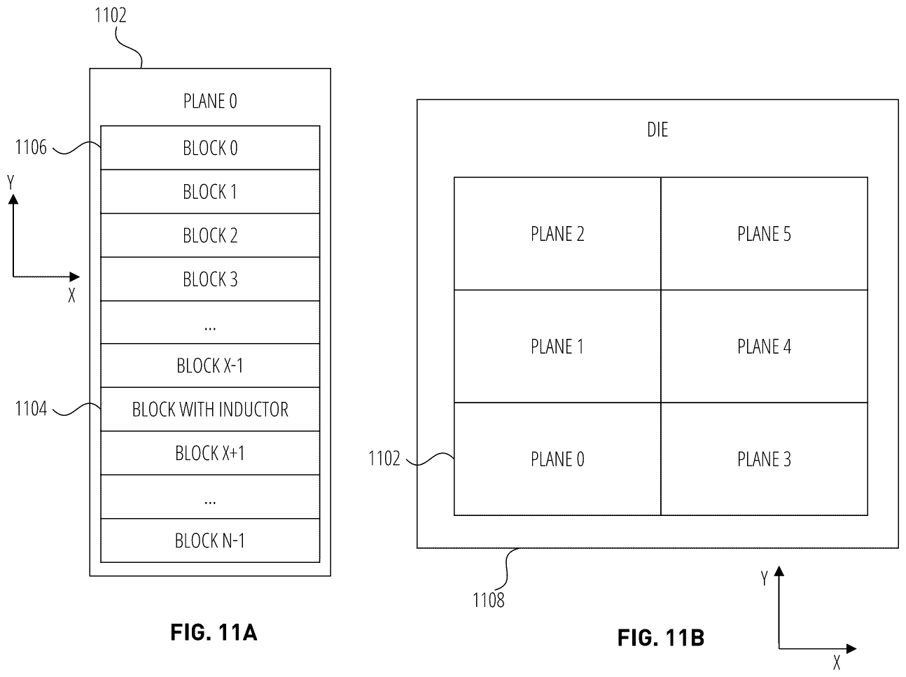

FIG. 11A illustrates an example NAND plane 1102 with an on-chip inductor, according to some examples. The plane 1102 is formed of an array of blocks 1106 and a block with inductor 1104, according to some examples. The plane may have additional of fewer blocks 1106 and/or instances of the block with inductor 1104, according to some examples. The plane 1102 includes N blocks 1106, numbered 0 to N−1, according to some examples. For example, each plane 1102 has N=714 blocks 1106.

Each block 1106 is a two-dimensional matrix of NAND cells and peripheral circuitry, including a number of pages and strings. The total number of NAND cells in a block 1106 can be found by multiplying the number of pages by the number of strings. Each block 1106 in the plane 1102 can have the same dimensions (e.g., number of pages and number of strings), according to some examples.

A string is a number of NAND cells along a bit line (BL) and, for example, form the columns of the block 1106. According to some examples, a string contains 32, 64, 96, 128, or 232 NAND cells. All strings in a memory array are connected at one end to a common source line. Each string further contains two control mechanisms in series with the NAND cells: (1) a string select transistor connected via a string select line and (2) a ground select transistor connected via a ground select line.

A page is a number of NAND cells along a word line and, for example, form the rows of the block 1106. According to some examples, a page contains 32 k, 64 k, or 128 k NAND cells, though the page size may be referred to in bytes (e.g., 4 k, 8 k, etc., bytes).

The block with inductor 1104 is a 3D NAND memory block that includes an inductor. The inductor is, for example, in the space adjacent to the memory array region. The inductor is part of a boost converter for supplying power to the memory block, according to some examples. The inductor may be any inductor described herein, such as inductor 700, inductor 800, or inductor 900.

According to some examples, the block with inductor 1104 is formed on-chip in an area that could alternatively hold a block 1106, and vice versa. That is, the block with inductor 1104 has the same dimensions as the other blocks 1106 in the plane 1102. For example, the block with inductor 1104 is formed between two blocks 1106, block x−1 and block x+1, where x is any number less than N−1 and greater than 0. Additionally, or alternatively, the block with inductor 1104 may be formed at an end block of the plane, e.g., in the place of block 0 or block N−1. The illustration of the location of the block with inductor 1104 in FIG. 11A is not meant to be limiting.

The formation of the block with inductor 1104 uses existing NAND structures, according to some examples. For example, take a 3D NAND structure with 232 tiers that is approximately ˜10's of microns tall. Thus, the inductor formed in the block with inductor 1104 has a cross-sectional area equivalent to ˜10's of microns times the width of the set of lower connections. The inductance of a solenoid is proportional to the cross-sectional area of the solenoid:

where L represents inductance, n represents the number of turns in the solenoid, μ₀ is the permeability of free space (i.e., 4×10⁻⁷ Henries/meter), a represents the cross-sectional area of the solenoid, and l represents the length of the solenoid. Thus, the inductor in the block with inductor 1104 has an inductance proportional to its relatively large cross-sectional area and further proportional to a square of the number of turns. Accordingly, the block with inductor 1104 has an inductance that is sufficiently high to be commercially viable and useful for on-chip functions.

FIG. 11B illustrates an example NAND die 1108, according to some examples. Each die 1108 includes a number of planes 1102. The number of planes 1102 and geometry of organizing the planes 1102 on the die 1108 may vary according to different examples. In the example depicted in FIG. 11B, the die 1108 includes six planes 1102, where each plane 1102 shares two sides with two other planes 1102 and has two open ended sides.

A memory device includes a memory controller and a memory array including, for examples, a number of individual memory die (e.g., die 1108). In other words, the die 1108 with at least one block with inductor 1104 is used in a memory device, according to some examples. Such a memory device can be used in various electronic devices.

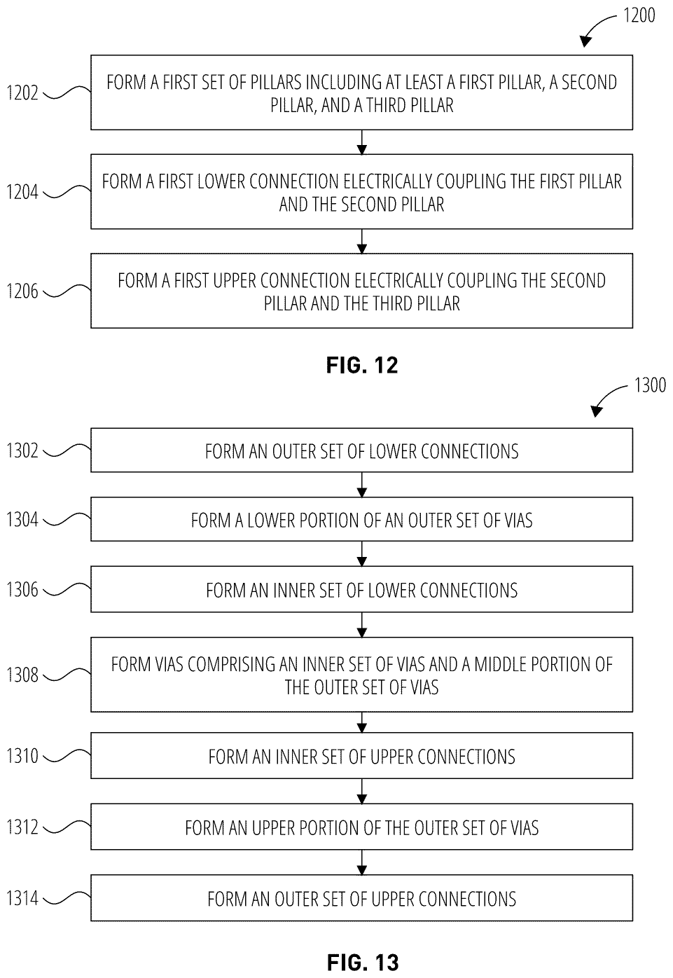

FIG. 12 is a flow diagram of features of an example method 1200 of forming an inductor, according to some examples. The method 1200 can be used to form the inductor 700, the inductor 800, the inductor 900, or any combination thereof, according to some examples.

At 1202, a first set of vias are formed, the first set of vias including at least a first via, a second via, and a third via. According to some examples, the set of vias comprises a first row of vias and a second row of vias, where the first row of vias is parallel to the second row of vias. The first set of vias may be formed during fabrication of vias of a 3D NAND circuit on a die with the inductor.

At 1204, a first lower connection is formed, the first lower connection electrically connecting the first via to the second via. According to some examples, the first lower connection is formed by applying a hard mask to a top surface, etching at least one lower-connection-shaped hole into the hard mask, and filling the at least one lower-connection-shaped hole with a metal to form the first lower connection. According to some examples, the metal is tungsten. According to some examples, the first lower connection is formed prior to formation of the first set of vias. According to some examples, the first lower connection belongs to a set of lower connections. The set of lower connections is formed by the same process by forming the desired number of holes in the hard mask.

At 1206, a first upper connection is formed, the first upper connection electrically connecting the second via to the third via. According to some examples, the first upper connection is formed by applying a hard mask to the top surface of the first set of vias, etching at least one upper-connection-shaped hole into the hard mask, and filling the at least one upper-connection shaped hole with a conductive material to form the first upper connection. According to some examples, the first upper connection is formed after formation of the first lower connection and the first set of vias. According to some examples, the first upper connection belongs to a set of upper connections. The set of upper connections is formed by the same process by forming the desired number of holes in the hard mask.

According to some examples, the first set of vias contains additional vias. In some examples, each via in the first set of vias is electrically connected to at least one other via in the set of vias via a lower connection in the set of lower connections and/or an upper connection in the set of upper connections. According to some examples, each electrical connection between a via and a connection (e.g., upper connection or lower connection) comprises a plurality of parallel contacts that helps lower resistance characteristics of the signal path connecting the vias and connections.

Variations of the method 1200 or methods similar to the method 1200 can include a number of different embodiments that may be combined depending on the application of such methods or the architecture or process flow of an integrated circuit for which such methods are implemented. Such methods can include inductors such as inductor 700, inductor 800, or inductor 900, or a combination thereof, according to some examples.

Variations of the method 1200 or methods similar to the method 1200 can include or use, for example, a magnetic core. For example, a magnetic core can be formed by forming a block of oxide, etching the block of oxide to form an oblong hole oriented between the first row of vias and the second row of vias, and at least partially filling the oblong hole with a ferromagnetic material to form a magnetic core. According to some examples, the remainder of the oblong hole is filled with an oxide after formation of the core.

Variations of the method 1200 or methods similar to the method 1200 can include, for example, formation of two or more nested solenoids, such as in the example of the inductor 900. According to some examples, the method 1200 is modified to form an inner solenoid. The inner solenoid is contained within the first set of vias, the first upper connection, and the first lower connection. According to some examples, the inner solenoid is formed by forming a second set of vias, each via in the second set of vias being conductive and being oriented parallel to one another, the second set of vias including at least a fourth via, a fifth via, and a sixth via. A second lower connection is formed, the second lower connection electrically connecting the fourth via and the fifth via. A second upper connection is formed, the second upper connection electrically connecting the fifth via and the sixth via, according to some examples.

The method 1200 can be used to form an inductor designed to have a desired inductance and/or q-factor. For example, designable parameters such as the dimensions (e.g., length, width, height) of the inductor, shape and/or dimensions of the vias and connections (e.g., the set of vias, the set of lower connections, the set of upper connections), inclusion of a magnetic core and magnetic characteristics of the material of the core, and inclusion of a second inner solenoid, among other parameters, can be modified to achieve a desired inductance and/or q-factor.

FIG. 13 is a flow diagram of features of an example method 1300 of forming a nested inductor, according to some examples. The nested inductor comprises an outer solenoid and an inner solenoid. The method 1300 can be used to form the inductor 900, according to some examples. The method 1300 can be an additive layering process.

At 1302, an outer set of lower connections are formed. The outer set of lower connections may be an example of the outer set of lower connections 908 of FIG. 9. According to some examples, the outer set of lower connections can be formed by applying a hard mask to a top surface, etching at least one lower-connection-shaped hole into the hard mask, and filling the at least one lower-connection-shaped hole with a metal to form the outer set of lower connections. According to some examples, the metal is tungsten.

At 1304, a lower portion of an outer set of vias are formed. The outer set of vias may be an example of the outer set of vias 906 of FIG. 9. The lower portion of the outer set of vias may be of a z-directional height spanning from the outer set of lower connections to an inner set of lower connections. The vias may be formed, for example, as part of 3D NAND fabrication. Additionally, or alternatively, the vias may be formed using a damascene process or any process discussed in relation to the formation of the set of vias 702 of FIG. 7.

At 1306, the inner set of lower connections are formed. The inner set of lower connections may be an example of the inner set of lower connections 914 of FIG. 9. The inner set of lower connections may be formed by methods discussed in relation to 1302.

At 1308, vias are formed, the vias comprising an inner set of vias and a middle portion of the outer set of vias. The inner set of vias may be an example of the inner set of vias 912 of FIG. 9. The middle portion of the outer set of vias may be of a z-directional height approximately equal to a z-directional height of the inner set of vias. The middle portion of the outer set of vias may be formed directly on top of and in alignment with the lower portion of the outer set of vias. The vias may be formed by methods discussed in relation to 1304.

At 1310, an inner set of upper connections are formed. The inner set of upper connections may be an example of the inner set of upper connections 916 of FIG. 9. According to some examples, the inner set of upper connections may be formed by a metallization process, such as those discussed in relation to the set of upper connections 706 of FIG. 7.

At 1312, an upper portion of an outer set of vias are formed. The upper portion of the outer set of vias may be of a z-directional height spanning from the inner set of upper connections to an outer set of upper connections. The upper portion of the vias may be formed directly on top of and in alignment with the middle portion of the outer set of vias. The lower portion, middle portion, and upper portion of each via in the outer set of vias are electrically connected. The upper portion of the outer set of vias may be formed by any methods of forming vias discussed in relation to 1304.

At 1314, the outer set of upper connections are formed. The outer set of upper connections may be an example of the outer set of upper connections 910 of FIG. 9. The outer set of upper connections may be formed by any methods discussed in relation to 1310.

Variations of the method 1300 or methods similar to the method 1300 can include a number of different embodiments that may be combined depending on the application of such methods or the architecture or process flow of an integrated circuit for which such methods are implemented.

Variations of the method 1300 or methods similar to the method 1300 can include or use, for example, a magnetic core. The magnetic core may be an example of magnetic core 940 of FIG. 9. The magnetic core may be formed by forming a block of oxide, etching the block of oxide to form an oblong hole oriented between the first row of vias and the second row of vias, and at least partially filling the oblong hole with a ferromagnetic material to form a magnetic core. According to some examples, the remainder of the oblong hole is filled with an oxide after formation of the core.

The method 1300 can be used to form an inductor designed to have a desired inductance and/or q-factor. For example, designable parameters such as the dimensions (e.g., length, width, height) of the inner and outer solenoids, shape and/or dimensions of the vias and connections (e.g., the outer set of vias, the inner set of vias, the outer set of lower connections, the inner set of lower connections, the outer set of upper connections, and the inner set of upper connections), inclusion of a magnetic core and magnetic characteristics of the material of the core, among other parameters, can be modified to achieve a desired inductance and/or q-factor for commercial use.

Reference throughout this specification to “one embodiment” or “an embodiment” means that a particular feature, structure, or characteristic described in connection with the embodiment is included in at least one embodiment of claimed subject matter. Thus, the appearances of the phrase “in one embodiment” or “an embodiment” in various places throughout this specification are not necessarily all referring to the same embodiment. Furthermore, the particular features, structures, or characteristics may be combined in one or more embodiments.

To better illustrate the inductor structures and formation or fabrication techniques described herein, a non-limiting set of Example embodiments are set forth below as numerically identified Examples.

Example 1 is an apparatus comprising: a memory circuit comprising at least one three-dimensional (3D) NAND memory component, the at least one 3D NAND memory component comprising a plurality of memory cells; and an inductor comprising: a first set of vias, each via of the first set of vias being conductive and having a central axis that is parallel to central axes of the other vias of the first set of vias, the first set of vias including at least a first via, a second via, and a third via; a first lower connection electrically connecting the first via and the second via; and a first upper connection electrically connecting the second via and the third via, wherein an electrical signal path continuously extends from the first via, to the first lower connection, to the second via, to the first upper connection, and the electrical signal path forms a first turn of the inductor.

Example 2 is the apparatus of example 1, wherein the inductor further comprises: a ferromagnetic core disposed at least partially inside the first turn of the inductor.

Example 3 is the apparatus of example 2, wherein the at least one 3D NAND memory component further comprises at least one oxide layer and at least one nitride layer, and wherein the first set of vias of the inductor extend through the at least one oxide layer and the at least one nitride layer.

Example 4 is the apparatus of example 1, the inductor further comprising: a second set of vias arranged in parallel orientation, the second set of vias including at least a fourth via, a fifth via, and a sixth via; a second lower connection electrically connecting the fourth via and the fifth via; and a second upper connection electrically connecting the fifth via and the sixth via, wherein a second electrical signal path extends from the fourth via, to the second lower connection, to the fifth via, to the second upper connection, and the second electrical signal path forms a second turn of the inductor.

Example 5 is the apparatus of example 4, wherein the first turn of the inductor belongs to an outer solenoid and the second turn of the inductor belongs to an inner solenoid, and wherein the second set of vias being contained within the confines of the first set of vias, the first upper connection, and the first lower connection.

Example 6 is the apparatus of example 4, wherein the inductor further comprises: a ferromagnetic core contained within the confines of the second set of vias, the second upper connection, and the second lower connection.

Example 7 is the apparatus of example 1, wherein the first lower connection electrically connecting the first via and the second via further comprises: a first plurality of contacts, the first plurality of contacts connecting the first via to the first lower connection; and a second plurality of contacts, the second plurality of contacts connecting the first lower connection to the second via.

Example 8 is the apparatus of example 7, wherein each contact in the first plurality of contacts has a cross-sectional shape of square, longitudinal rectangle, or transverse rectangle.

Example 9 is the apparatus of example 1, the apparatus further comprising: a boost converter configured to supply voltage to the memory circuit, the boost converter comprising the inductor.

Example 10 is a method of forming an on-chip inductor on a first die, the method comprising: forming a first set of vias adjacent to vias of a NAND memory circuit on the first die, the first set of vias being arranged in parallel orientation on the first die, the first set of vias including at least a first via, a second via, and a third via; forming a first lower connection electrically connecting the first via and the second via; and forming a first upper connection electrically connecting the second via and the third via, wherein an electrical path that extends from the first via, to the first lower connection, to the second via, to the first upper connection, forms a first turn of the inductor.

Example 11 is the method of example 10, wherein forming the first lower connection further comprises: applying a hard mask to a top surface; etching at least one lower-connection-shaped hole into the hard mask; and filling the at least one lower-connection-shaped hole with tungsten to form the first lower connection.

Example 12 is the method of example 10, wherein forming the first upper connection further comprises: applying a hard mask to the top surface of the first set of vias; etching at least one upper-connection-shaped hole into the hard mask; and filling the at least one upper-connection shaped hole with a conductive material to form the first upper connection.

Example 13 is the method of example 10, wherein the first set of vias are formed during fabrication of vias of the 3D NAND circuit on the first die.

Example 14 is the method of example 10, wherein the set of vias comprises a first row of vias and a second row of vias, where the first row of vias is parallel to the second row of vias.

Example 15 is the method of example 14, further comprising: forming a block of oxide; etching the block of oxide to form an oblong hole oriented between the first row of vias and the second row of vias; and at least partially filling the oblong hole with a ferromagnetic material to form a magnetic core.

Example 16 is the method of example 15, further comprising: filling the remainder of the oblong hole with an oxide.

Example 17 is the method of example 10, wherein the first turn of the inductor is a first turn of an outer solenoid of the inductor, further comprising: forming an inner solenoid, the inner solenoid being contained within the first set of vias, the first upper connection, and the first lower connection, the forming the inner solenoid comprising: forming a second set of vias arranged in parallel orientation, the second set of vias including at least a fourth via, a fifth via, and a sixth via; forming a second lower connection electrically connecting the fourth via and the fifth via; and forming a second upper connection electrically connecting the fifth via and the sixth via wherein an electrical path that extends from the fourth via, to the second lower connection, to the fifth via, to the second upper connection, forms a first turn of the inner solenoid.

Example 18 is the method of example 10, wherein the inductor is formed as a component of a boost converter to supply power to a 3D NAND memory array.

Example 19 is an integrated circuit-based inductor comprising: an outer solenoid comprising: a first set of vias arranged in parallel orientation, the first set of vias including at least a first via, a second via, and a third via; a first lower connection electrically connecting the first via and the second via; and a first upper connection electrically connecting the second via and the third via, wherein an electrical path that extends from the first via, to the first lower connection, to the second via, to the first upper connection, forms a first turn of the outer solenoid; and an inner solenoid comprising: a second set of vias arranged in parallel orientation, the second set of vias including at least a fourth via, a fifth via, and a sixth via; a second lower connection electrically connecting the fourth via and the fifth via; and a second upper connection electrically connecting the fifth via and the sixth via, wherein an electrical path that extends from the fourth via, to the second lower connection, to the fifth via, to the second upper connection, forms a first turn of the inner solenoid.

Example 20 is the apparatus of example 19, wherein the inductor further comprises: a ferromagnetic core disposed at least partially inside the first turn of the inner solenoid.

Example 21 is an apparatus comprising means to implement of any of Examples 1-20.

Example 22 is a system to implement of any of Examples 1-20.

Example 23 is a method to implement of any of Examples 1-11 or Example 20.

Each of these non-limiting examples can stand on its own or can be combined in various permutations or combinations with one or more of the other examples.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” can include “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) can be used in combination with each other. Other embodiments can be used, such as by one of ordinary skill in the art upon reviewing the above description. It is submitted with the understanding that it will not be used to interpret or limit the scope or meaning of the claims. Also, in the above Detailed Description, various features can be grouped together to streamline the disclosure. This should not be interpreted as intending that an unclaimed disclosed feature is essential to any claim. Rather, inventive subject matter can lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. An apparatus comprising:
a memory circuit comprising at least one three-dimensional (3D) NAND memory component, the at least one 3D NAND memory component comprising a plurality of memory cells; and
an inductor comprising:
a first set of vias, each via of the first set of vias being conductive and having a central axis that is parallel to central axes of the other vias of the first set of vias, the first set of vias including at least a first via, a second via, and a third via;
a first lower connection electrically connecting the first via and the second via; and
a first upper connection electrically connecting the second via and the third via, wherein an electrical signal path continuously extends from the first via, to the first lower connection, to the second via, to the first upper connection, and the electrical signal path forms a first turn of the inductor.

2. The apparatus of claim 1, wherein the inductor further comprises:
a ferromagnetic core disposed at least partially inside the first turn of the inductor.

3. The apparatus of claim 2, wherein the at least one 3D NAND memory component further comprises at least one oxide layer and at least one nitride layer, and wherein the first set of vias of the inductor extend through the at least one oxide layer and the at least one nitride layer.

4. The apparatus of claim 1, the inductor further comprising:
a second set of vias arranged in parallel orientation, the second set of vias including at least a fourth via, a fifth via, and a sixth via;
a second lower connection electrically connecting the fourth via and the fifth via; and
a second upper connection electrically connecting the fifth via and the sixth via, wherein a second electrical signal path extends from the fourth via, to the second lower connection, to the fifth via, to the second upper connection, and the second electrical signal path forms a second turn of the inductor.

5. The apparatus of claim 4, wherein the first turn of the inductor belongs to an outer solenoid and the second turn of the inductor belongs to an inner solenoid, and wherein the second set of vias being contained within the confines of the first set of vias, the first upper connection, and the first lower connection.

6. The apparatus of claim 4, wherein the inductor further comprises:
a ferromagnetic core contained within the confines of the second set of vias, the second upper connection, and the second lower connection.

7. The apparatus of claim 1, wherein the first lower connection electrically connecting the first via and the second via further comprises:
a first plurality of contacts, the first plurality of contacts connecting the first via to the first lower connection; and
a second plurality of contacts, the second plurality of contacts connecting the first lower connection to the second via.

8. The apparatus of claim 7, wherein each contact in the first plurality of contacts has a cross-sectional shape of square, longitudinal rectangle, or transverse rectangle.

9. The apparatus of claim 1, the apparatus further comprising:
a boost converter configured to supply voltage to the memory circuit, the boost converter comprising the inductor.

10. A method of forming an on-chip inductor on a first die, the method comprising:
forming a first set of vias adjacent to vias of a NAND memory circuit on the first die, the first set of vias being arranged in parallel orientation on the first die, the first set of vias including at least a first via, a second via, and a third via;
forming a first lower connection electrically connecting the first via and the second via; and
forming a first upper connection electrically connecting the second via and the third via, wherein an electrical path that extends from the first via, to the first lower connection, to the second via, to the first upper connection, forms a first turn of the inductor.

11. The method of claim 10, wherein forming the first lower connection further comprises:
applying a hard mask to a top surface;
etching at least one lower-connection-shaped hole into the hard mask; and
filling the at least one lower-connection-shaped hole with tungsten to form the first lower connection.

12. The method of claim 10, wherein forming the first upper connection further comprises:
applying a hard mask to the top surface of the first set of vias;
etching at least one upper-connection-shaped hole into the hard mask; and
filling the at least one upper-connection shaped hole with a conductive material to form the first upper connection.

13. The method of claim 10, wherein the first set of vias are formed during fabrication of vias of the 3D NAND circuit on the first die.

14. The method of claim 10, wherein the set of vias comprises a first row of vias and a second row of vias, where the first row of vias is parallel to the second row of vias.

15. The method of claim 14, further comprising:
forming a block of oxide;
etching the block of oxide to form an oblong hole oriented between the first row of vias and the second row of vias; and
at least partially filling the oblong hole with a ferromagnetic material to form a magnetic core.

16. The method of claim 15, further comprising:
filling the remainder of the oblong hole with an oxide.

17. The method of claim 10, wherein the first turn of the inductor is a first turn of an outer solenoid of the inductor, further comprising:
forming an inner solenoid, the inner solenoid being contained within the first set of vias, the first upper connection, and the first lower connection, the forming the inner solenoid comprising:
forming a second set of vias arranged in parallel orientation, the second set of vias including at least a fourth via, a fifth via, and a sixth via;
forming a second lower connection electrically connecting the fourth via and the fifth via; and
forming a second upper connection electrically connecting the fifth via and the sixth via wherein an electrical path that extends from the fourth via, to the second lower connection, to the fifth via, to the second upper connection, forms a first turn of the inner solenoid.

18. The method of claim 10, wherein the inductor is formed as a component of a boost converter to supply power to a 3D NAND memory array.

19. An integrated circuit-based inductor comprising:
an outer solenoid comprising:
a first set of vias arranged in parallel orientation, the first set of vias including at least a first via, a second via, and a third via;
a first lower connection electrically connecting the first via and the second via; and
a first upper connection electrically connecting the second via and the third via, wherein an electrical path that extends from the first via, to the first lower connection, to the second via, to the first upper connection, forms a first turn of the outer solenoid; and
an inner solenoid comprising:
a second set of vias arranged in parallel orientation, the second set of vias including at least a fourth via, a fifth via, and a sixth via;
a second lower connection electrically connecting the fourth via and the fifth via; and
a second upper connection electrically connecting the fifth via and the sixth via, wherein an electrical path that extends from the fourth via, to the second lower connection, to the fifth via, to the second upper connection, forms a first turn of the inner solenoid.

20. The apparatus of claim 19, wherein the inductor further comprises:
a ferromagnetic core disposed at least partially inside the first turn of the inner solenoid.
